(19) United States
(12) Patent Application Publication
(10) Pub. No.: US 2008/0179762 A1
(43) Pub. Date: Jul. 31, 2008

(54) LAYERED STRUCTURE WITH LASER-INDUCED AGGREGATION SILICON NANO-DOTS IN A SILICON-RICH DIELECTRIC LAYER, AND APPLICATIONS OF THE SAME

(75) Inventors: An-Thung Cho, Hsin-Chu (TW); Chih-Wei Chao, Hsin-Chu (TW); Chia-Tien Peng, Hsin-Chu (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: AU Optronics Corporation, Hsinchu (TW)

(21) Appl. No.: 11/876,516

(22) Filed: Oct. 22, 2007

Related U.S. Application Data
(63) Continuation-in-part of application No. 11/698,261, filed on Jan. 25, 2007.

(51) Int. Cl. H01L 29/788; H01L 21/00; H01L 31/00; H01L 21/336; B05D 5/12; H01L 31/06

(52) U.S. Cl. 257/E31.001; 257/321; 136/258; 257/461; 438/264; 438/63; 257/E21.409; 257/E29.3; 427/74

(57) ABSTRACT

The present invention relates to a layered structure with laser-induced aggregation silicon nano-dots in a silicon-rich dielectric layer, where the laser-induced aggregation silicon nano-dots are formed by a laser-induced aggregation process applied to the silicon-rich dielectric layer, and applications of the same. In one embodiment, the silicon-rich dielectric layer is one of a silicon-rich oxide film having a refractive index in the range of about 1.4 to 2.3, and a silicon-rich nitride film having a refractive index in the range of about 1.7 to 2.3. The layered structure with laser-induced aggregation silicon nano-dots in a silicon-rich dielectric layer is usable in a solar cell, a photosensitive element, a touch panel, a non-volatile memory device as storage node, and a display panel, respectively.

### CROSS-REFERENCE TO RELATED PATENT APPLICATION

This application is a continuation-in-part of U.S. patent application Ser. No. 11/698,261, entitled “METHODS OF FORMING SILICON NANOCRYSTALS BY LASER ANNEALING” by An-Thung CHO, Chih-Wei CHAO, and Chia-Tien PENG, which was filed on Jan. 25, 2007, and with the same assignee as that of this application. The disclosure of the above identified co-pending application is incorporated herein by reference in its entirety.

Some references, if any, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference.

### FIELD OF THE INVENTION

The present invention relates generally to a layered structure with laser-induced aggregation silicon nano-dots in a silicon-rich dielectric layer and, more particularly, to a layered structure with laser-induced aggregation silicon nano-dots in a silicon-rich dielectric layer, where the laser-induced aggregation silicon nano-dots are formed by laser beam incident upon the silicon-rich dielectric film, and applications of the same.

### BACKGROUND OF THE INVENTION

Photovoltaic (PV) devices find their applications in many areas such as solar cells, touch panels, ambient light sensors, UV-Visible photodetectors, as well as full-color, high quality TFT flat panel display. Such photovoltaic devices may be fabricated with nano-dots. Traditionally, semiconductor materials such as Si, Ge are used to produce nano-dots based on the concepts of band gap and quantum confinement effects of these materials. Exemplary PV devices are disclosed in published U.S. Patent Application 2006/0189014, which is incorporated herein in its entirety by reference for background information only. One widely-used method of fabricating silicon nano-cluster is to precipitate the silicon nano-cluster out of SiOx (where x<2), producing a film using chemical vapor deposition, radio frequency (RF)-sputtering, or Si implantation. This film is often called silicon-rich silicon oxide (SRSO) or silicon-rich oxide (SRO). Using the CVD or RF-sputtering processes, with a high-temperature annealing, a photovoltaic (PV) peak in the SRSO can typically be obtained in the wavelength range of 590 nanometers (nm) to 750 nm. However, these SRO materials exhibit low quantum efficiency and have a stability problem, which reduces the PV intensity height over time, and limits their application to PV devices.

Er implantation, creating Er-doped nanocrystal Si, is also used in Si-based light sources. However, state-of-the-art implantation processes have not been able to distribute the dopant uniformly, which lowers the light emitting efficiency and increases costs. At the same time, there has been no interface engineering sufficient to support the use of such a dopant. Using the Si/SiO₂ superlattice structure to control crystal size results in a slow, high-temperature deposition process that cannot simultaneously control both the Si particle size and the quality Si nanocrystal/SiO₂ interface. The device efficiency is very low, which limits the device applications. In order to improve the device efficiency, a large interface area must be created between nano-dots Si and SiO₂.

On the other hand, the non-volatile-memory (“NVM”) market today is dominated by floating-gate (FG) devices. A conventional floating gate non-volatile-memory element is shown in FIG. 16. In FIG. 16, the floating gate NVM element 1600 has a source electrode, a drain electrode and a gate electrode. An inversion layer is formed on a P-type semiconductor substrate between the source electrode and the drain electrode. An insulation layer is formed between the floating gate and the gate electrode. The floating gate is surrounded by the insulation layer(s), therefore the storage of charge is in the floating-gate layer.

FIG. 17 shows a partial sectional view of a conventional silicon-oxide-nitride-oxide-silicon (SONOS) nonvolatile memory element 1700 that has a stacked structure. A source electrode and a drain electrode (not shown) are formed on a semiconductor substrate (not marked), and contacted with the source region 1710 and a drain region 1720 in the semiconductor substrate, respectively. The stacked structure has a first SiO₂ layer 1730 as a tunnel oxide layer, a polycrystalline silicon layer 1740, a second SiO₂ layer 1750, a Si₃N₄ layer 1760, a third SiO₂ layer 1770, and a conductive layer 1780 as gate electrode. The fabrication process of such conventional SONOS nonvolatile memory element is very complicated, and the scaling the tunnel oxide will lead to anomalous charge leakage.

According to the International Technology Roadmap for Semiconductors 2001 known to people skilled in the art, the tunnel oxide thickness of FG devices would remain at a level of about 5 nm for future generations. Scaling the tunnel oxide leads to anomalous charge leakage, which may be caused by only one or two defects in the oxide. Such a leakage causes the information stored in the non-volatile memory to be lost. Discrete charge storage bypasses this problem, hence allowing for scaling of the tunnel oxide and program/erase operating voltages. Reduction of the size of the charge pumps enabled by these lower voltages, as well as avoiding the double poly process required for FG devices, lowers the cost of integration especially important for embedded applications. This has triggered a renewed interest in NVM cells employing discrete, trap-like storage nodes.

Conventionally, silicon nano-dots embedded in silicon-rich nitride and silicon-rich oxide are used as the charge trapping medium to increase the retention and endurance of the information stored in the non-volatile memory devices must need high-temperature post-annealing process. However, due to aforementioned manufacturing difficulties, these materials are not easily integrated on a glass panel with conventional manufacturing process.

Therefore, it is apparent that a heretofore unaddressed need exists in the art to address the aforementioned deficiencies and inadequacies. In particular, a simple and efficient light-emitting device compatible with silicon, with a manufacturing process that does not require high temperature post annealing, with a process that is compatible with the conventional process to produce low temperature poly-silicon thin film transistor (LTPS-TFT) would be desirable in applications where photonic devices (light emitting and light detecting) are necessary.

### SUMMARY OF THE INVENTION

The present invention, in one aspect, relates to a solar cell. In one embodiment, the solar cell has: (i) a substrate, (ii) a bottom-conductive layer formed on the substrate, (iii) a first semiconductor layer, formed on the bottom-conductive layer, wherein the first semiconductor layer is doped with n+ or p+ to form a first N-doped or P-doped semiconductor layer, (iv) a silicon-rich dielectric layer having a plurality of laser-induced aggregation silicon nano-dots, wherein the silicon-rich dielectric layer is formed on the first N-doped or P-doped semiconductor layer, (v) a second semiconductor layer on the silicon-rich dielectric layer, wherein the second semiconductor layer is doped with p+ or n+ to form a second P-doped or N-doped semiconductor layer, and (vi) a top-conductive layer formed on the second P-doped or N-doped semiconductor layer. In one embodiment, at least one of the first semiconductor layer and the second semiconductor layer is made of amorphous silicon, poly silicon, micro-crystallized silicon, mono-crystallized silicon, or any combinations of these materials.

In one embodiment, the silicon-rich dielectric layer is made of silicon-rich oxide, silicon-rich nitride, silicon-rich oxy-nitride, silicon-rich carbide, or any combinations of these materials. In one embodiment, at least one of the first conductive layer and the second conductive layer is a transparent material layer. The transparent material layer is made of indium tin oxide (ITO), indium zinc oxide (IZO), aluminum zinc oxide (AZO), hafnium oxide (HfO), others, or any combinations of these materials.

In one embodiment, at least one of the first semiconductor layer and the second semiconductor layer has an N-type semiconductor, a P-type semiconductor, a laser crystallized N-type semiconductor, a laser crystallized P-type semiconductor, or any combinations of these semiconductors. The laser crystallized N-type semiconductor and the laser crystallized P-type semiconductor are formed by a laser crystallization process.

In one embodiment, at least one of the substrate, the first semiconductor layer, and the second semiconductor layer is made of transparent material, opaque material, reflective material, or any combinations these materials.

In another aspect, the present invention relates to a method for forming a solar cell. In one embodiment, the method includes: (i) providing a substrate, (ii) forming a bottom-conductive layer on the substrate, (iii) forming a first semiconductor layer on the bottom-conductive layer, (iv) doping the first semiconductor layer to form a first N-doped or P-doped semiconductor layer, (v) forming a silicon-rich dielectric layer on the first N-doped or P-doped semiconductor layer, (vi) forming a plurality of laser-induced aggregation silicon nano-dots by applying a laser beam incident upon the silicon-rich dielectric layer, (vii) forming a second semiconductor layer on the silicon-rich dielectric layer with a plurality of laser-induced aggregation silicon nano-dots, and (viii) doping the second semiconductor layer to form forming a second P-doped or N-doped semiconductor layer.

In one embodiment, the step of doping the first semiconductor layer to form a first N-doped or P-doped semiconductor layer includes the step of performing implantation process on the first semiconductor layer. In another embodiment, the step of doping the first semiconductor layer to form a first N-doped or P-doped semiconductor layer includes the step of applying in-situ plasma-CVD doping process on the first conductive layer.

In one embodiment, the step of doping the second semiconductor layer to form a second P-doped or N-doped semiconductor layer includes the step of performing implantation process on the second semiconductor layer. In another embodiment, the step of doping the second semiconductor layer to form a second P-doped or N-doped semiconductor layer includes the step of applying in-situ plasma-CVD doping process on the silicon-rich dielectric layer with the plurality of laser-induced aggregation silicon nano-dots.

In one embodiment, the method for forming a solar cell further includes the step of forming a top conductive layer on the second semiconductor layer.

In one embodiment, at least one of the first semiconductor layer and the second semiconductor layer is made of amorphous silicon, poly silicon, micro-crystallized silicon, mono-crystallized silicon, or any combinations of these materials. The silicon-rich dielectric layer has silicon-rich oxide, silicon-rich nitride, silicon-rich oxy-nitride, silicon-rich carbide, or any combinations of these materials. In one embodiment, at least one of the first semiconductor layer and the second semiconductor layer is an N-type semiconductor, a P-type semiconductor, a laser crystallized N-type semiconductor, a laser crystallized P-type semiconductor, or any combinations of these semiconductors. The laser crystallized N-type semiconductor and the laser crystallized P-type semiconductor are formed by a laser crystallization process.

In one embodiment, at least one of the substrate, the first semiconductor layer, and the second semiconductor layer is made of transparent material, opaque material, reflective material, or any combinations of these materials. In one embodiment, during the laser crystallization process to form a laser crystallized N-type or P-type semiconductor, the laser irradiation is delivered to at least one of the first semiconductor layer and the second semiconductor layer along any desired directions through one or more transparent layers. In another embodiment, during the laser-induced aggregation process, the laser irradiation is delivered to the silicon-rich dielectric layer along any desired directions through one or more transparent layers.

In yet another aspect, the present invention relates to another method for forming a solar cell. In one embodiment, the method includes the steps of: (i) providing a substrate, (ii) forming a multi-layer structure with at least two layers on the substrate, wherein each layer of the multi-layer structure has a first state and a second state, and (iii) irradiating a laser beam to the multi-layer structure to allow at least one layer of the multi-layer structure to change from the first state to the second state. The first state of each layer of the multi-layer structure has a non-crystallized state. At least one layer of the multi-layer structure, has a plurality of laser-induced aggregation silicon nano-dots, and is at a corresponding second state that is a substantially non-crystallized state. The second state of at least two layers of the multi-layer structure has a substantially crystallized state, a substantially micro-crystallized state, or a non-crystallized state. The substantially crystallized state or a substantially micro-crystallized state is caused by a laser crystallization process.

In one embodiment, the method further includes the step of forming a first conductive layer between the substrate and the multi-layer structure. In another embodiment, the method further includes the step of forming a second conductive layer on the multi-layer structure. At least one of the substrate, one or more layers of the multi-layer structure, the first conductive layer, and the second conductive layer is made of a transparent material, opaque material, reflective material, or any combinations of these materials. The laser beam is delivered to the multi-layer structure along any desired directions through one or more transparent layers.

In a further aspect, the present invention relates to a nonvolatile memory element. In one embodiment, the nonvolatile memory element has: (i) a substrate, (ii) a semiconductor layer having a source region (n+ or p+) and a drain region (n+ or p+), (iii) a charged storage layer is a silicon-rich dielectric layer formed on the tunnel dielectric layer, and having a plurality of laser-induced aggregation silicon nano-dots, and (iv) a conductive layer (is as a Control Gate) is formed on the charged storage layer. The conductive layer is made of transparent material, opaque material, reflective material, or any combinations of these materials. The semiconductor layer is made of amorphous silicon, poly silicon, micro-crystallized silicon, mono-crystallized silicon, or any combinations of these materials. The silicon-rich dielectric layer is made of silicon-rich oxide, silicon-rich nitride, silicon-rich oxy-nitride, silicon-rich carbide, or any combinations of these materials.

In one embodiment, the nonvolatile memory element further includes a source electrode and a drain electrode electrically coupled to the source region and the drain region, respectively.

In one embodiment, the nonvolatile memory element further includes a buffer layer formed between the substrate and the semiconductor layer.

In one embodiment, the nonvolatile memory element further includes a tunnel dielectric layer formed on the semiconductor layer.

In one embodiment, the nonvolatile memory element includes an N-type semiconductor, a P-type semiconductor, a laser crystallized N-type semiconductor, a laser crystallized P-type semiconductor, or any combinations of these materials. The laser crystallized N-type semiconductor and the laser crystallized P-type semiconductor are formed by a laser crystallization process.

In another aspect, the present invention relates to a method for forming a nonvolatile memory element. In one embodiment, the method includes: (i) providing a buffer dielectric layer on a substrate, (ii) providing a semiconductor layer on the buffer dielectric layer, wherein a source region (n+, or p+), an intrinsic channel region (n-channel, or p-channel), and a drain region (n+, or p+) are formed in the semiconductor layer, respectively, (iii) forming a silicon-rich dielectric layer on the semiconductor layer, (iv) forming a plurality of laser-induced aggregation silicon nano-dots by applying a laser-induced aggregation process on the silicon-rich dielectric layer, and (v) forming a conductive layer (is as a control gate) on the silicon-rich dielectric layer with the plurality of laser-induced aggregation silicon nano-dots.

In one embodiment, the semiconductor layer is made of amorphous silicon, poly silicon, micro-crystallized silicon, mono-crystallized silicon, or any combinations of these materials. The conductive layer is made of transparent conductive material, opaque material, reflective conductive material, or any combinations of these materials.

In one embodiment, the method further includes providing a source electrode and a drain electrode electrically coupled to the source region and the drain region, respectively.

In other embodiment, the method further includes providing a tunnel dielectric layer on the semiconductor layer.

In one embodiment, the method further includes providing a buffer dielectric layer on the substrate and the semiconductor layer.

In one embodiment, the semiconductor layer includes an N-type semiconductor, a P-type semiconductor, a laser crystallized N-type semiconductor, a laser crystallized P-type semiconductor, or any combinations of these semiconductors. The laser crystallized N-type semiconductor and the laser crystallized P-type semiconductor are formed by a laser crystallization process.

In one embodiment, at least one of the substrate, the semiconductor layer, and the conductive layer has transparent material, opaque material, reflective material, or any combinations of these materials. During the laser crystallization process, the laser irradiation is delivered to the semiconductor layer along any desired directions through one or more transparent layers. During the laser-induced aggregation process, the laser irradiation is delivered to the silicon-rich dielectric layer along any desired directions through one or more transparent layers.

In yet another aspect, the present invention relates to a photo sensitive element. In one embodiment, the photo sensitive element has: (i) a first conductive layer, (ii) a second conductive layer, and (iii) a silicon-rich dielectric layer formed between the first conductive layer and the second conductive layer. The silicon-rich dielectric layer has a plurality of laser-induced aggregation silicon nano-dots. The silicon-rich dielectric layer has silicon-rich oxide, silicon-rich nitride, silicon-rich oxy-nitride, silicon-rich carbide, or any combinations of these materials.

In one embodiment, the first conductive layer is formed on a substrate. At least one of the first conductive layer, the second conductive layer and the substrate has transparent material, opaque material, reflective material, or any combinations of these materials. One or more photo sensitive elements are used to form a photo detector

The photo sensitive element can be used as photo detector/sensor, light sensor, and display panel. The display panel can be used in a touch panel, finger-print sensor, and ambient light sensor.

In a further aspect, the present invention relates to a method for forming a photo sensitive element. In one embodiment, the method includes: (i) providing a first conductive layer, (ii) forming a silicon-rich dielectric layer on the first conductive layer, (iii) applying a laser-induced aggregation process to the silicon-rich dielectric layer to form a plurality of laser-induced aggregation silicon nano-dots in the silicon-rich dielectric layer, and (iv) forming a second conductive layer on the silicon-rich dielectric layer. In one embodiment, the method further includes the step of providing a substrate such that the first conductive layer is formed on the substrate. At least one of the first conductive layer the second conductive layer and the substrate is made of transparent material, opaque material, reflective material, or any combinations of these materials. In one embodiment, the silicon-rich dielectric layer is made of silicon-rich oxide, silicon-rich nitride, silicon-rich oxy-nitride, silicon-rich carbide, or any combinations of these materials. During the laser-induced aggregation process, the laser irradiation is delivered to the silicon-rich dielectric layer along any desired directions through one or more transparent layers.

In an additional aspect, the present invention includes a layered structure with a plurality of laser-induced aggregation silicon nano-dots in a silicon-rich dielectric layer. In one embodiment, the layered structure has: (i) a substrate, (ii) a first conductive layer formed on the substrate, and (iii) a silicon-rich dielectric layer formed on the first conductive layer, wherein the silicon-rich dielectric layer has a plurality of laser-induced aggregation silicon nano-dots. In one embodiment, the silicon-rich dielectric layer is made of silicon-rich oxide, silicon-rich nitride, silicon-rich oxy-nitride, silicon-rich carbide, or any combinations of these materials. In one embodiment, preferred, the silicon-rich oxide layer has a refractive index in the range of about 1.47 to about 2.3, and the silicon-rich nitride layer has a refractive index in the range of about 1.7 to about 2.3. At least some of the silicon nano-dots have diameters ranging from about 2 nm to about 10 nm.

In one embodiment, preferred, the density of the laser-induced aggregation silicon nano-dots range from about 1×1011/cm2 to about 1×1012/cm2. In one embodiment, the layered structure also includes a second conductive layer. At least one of the first conductive layer and second conductive layer is made of transparent material, opaque material, reflective material, or any combinations of these materials.

The layered structure can be used as a solar cell, a photo sensitive element, and a display panel. The display panel can further be used in a touch panel. In one embodiment, a non-volatile memory device incorporating the layered structure and at least some of the plurality of laser-induced aggregation silicon nano-dots are used as storage nodes.

For the various methods of the present invention disclosed in this disclosure, each of them has several steps and these steps can be practiced in one or more orders.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the present invention and, together with the written description, serve to explain the principles of the invention. Wherever possible, the same reference numbers are used throughout the drawings to refer to the same or like elements of an embodiment, and wherein:

FIG. 1 shows a sectional view of a layered structure with laser-induced aggregation silicon nano-dots in a silicon-rich dielectric layer according to one embodiment of the present invention;

FIGS. 2(A)-(D) show a process of making a layered structure with laser-induced aggregation silicon nano-dots in a silicon-rich dielectric layer according to one embodiment of the present invention;

FIG. 3 shows a block diagram of the process as illustrated in FIG. 2, illustrating how the layered structure with laser-induced aggregation silicon nano-dots in a silicon-rich dielectric layer is manufactured according to one embodiment of the present invention;

FIGS. 4A-4D show four sectional views of various embodiments of solar cells using the layered structure with a plurality of laser-induced aggregation silicon nano-dots in a silicon-rich dielectric layer: (A) without a first conductive layer, (B) with a first conductive layer, (C) with a second conductive layer and without a first conductive layer, and (D) with both a first conductive layer and a second conductive layer, respectively.

FIGS. 5A-5I illustrate the processes of manufacturing a solar cell using the layered structure with a plurality of laser-induced aggregation silicon nano-dots in a silicon-rich dielectric layer according to embodiments of the present invention;

FIG. 6 demonstrates a multi-band gap solar cell spectrum divided into a plurality of narrow regions to produce high-efficiency solar cell according to one embodiment of the present invention.

FIGS. 7A-7C show three sectional views of nonvolatile memory elements using the layered structure with a plurality of laser-induced aggregation silicon nano-dots in a silicon-rich dielectric layer according to embodiments of the present invention;

FIGS. 8A-8F illustrate the processes of manufacturing a nonvolatile memory element using the layered structure with a plurality of laser-induced aggregation silicon nano-dots in a silicon-rich dielectric layer according to embodiments of the present invention.

FIGS. 9A-9C show the band-gap curves when electrons tunnel the tunneling oxide barrier into deep energy band of nano-dots (A) to write, (B) to store, and (C) to erase information in the silicon nonvolatile memory element according to embodiments of the present invention, respectively.

FIG. 10 shows a sectional view of a photo sensitive element using the layered structure with a plurality of laser-induced aggregation silicon nano-dots in a silicon-rich dielectric layer according to one embodiment of the present invention;

FIG. 11 shows a sketch of a portion of an application of a photo sensitive element using the layered structure with a plurality of laser-induced aggregation silicon nano-dots in a silicon-rich dielectric layer in conjunction with a readout thin film transistor (TFT) according to one embodiment of the present invention;

FIG. 12 shows a portion of a shared electronic circuit of four photo sensitive elements using the layered structure with a plurality of laser-induced aggregation silicon nano-dots in a silicon-rich dielectric layer according to one embodiment of the present invention;

FIG. 13 shows a sectional view of a readout thin film transistor and a photo sensitive element using the layered structure with a plurality of laser-induced aggregation silicon nano-dots in a silicon-rich dielectric layer integrated into a low temperature polycrystalline silicon panel according to one embodiment of the present invention;

FIG. 14 shows a sectional view of a readout thin film transistor and a photo sensitive element using the layered structure with a plurality of laser-induced aggregation silicon nano-dots in a silicon-rich dielectric layer integrated into a low temperature polycrystalline silicon panel with wide fill factor according to one embodiment of the present invention;

FIG. 15A shows a display panel made with a plurality of photo sensitive elements, a plurality of solar cells, an ambient light sensor, a photo detector, all using the layered structure with a plurality of laser-induced aggregation silicon nano-dots in a silicon-rich dielectric layer according to one embodiment of the present invention, and FIG. 15B shows one single cell of the layered structure used in a solar cell element, an ambient light sensor, a photo sensitive elements.

FIG. 16 shows a partial sectional view of a conventional floating gate flash memory element; and

FIG. 17 shows a partial sectional view of a conventional silicon-oxide-nitride-oxide-silicon (SONOS) nonvolatile memory element.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

The terms used in this specification generally have their ordinary meanings in the art, within the context of the invention, and in the specific context where each term is used.

Certain terms that are used to describe the invention are discussed below, or elsewhere in the specification, to provide additional guidance to the practitioner in describing the apparatus and methods of the invention and how to make and use them. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification. Furthermore, subtitles may be used to help a reader of the specification to read through the specification, which the usage of subtitles, however, has no influence on the scope of the invention.

As used herein, “about” or “approximately” shall generally mean within 20 percent, preferably within 10 percent, and more preferably within 5 percent of a given value or range. Numerical quantities given herein are approximate, meaning that the term “about” or “approximately” can be inferred if not expressly stated.

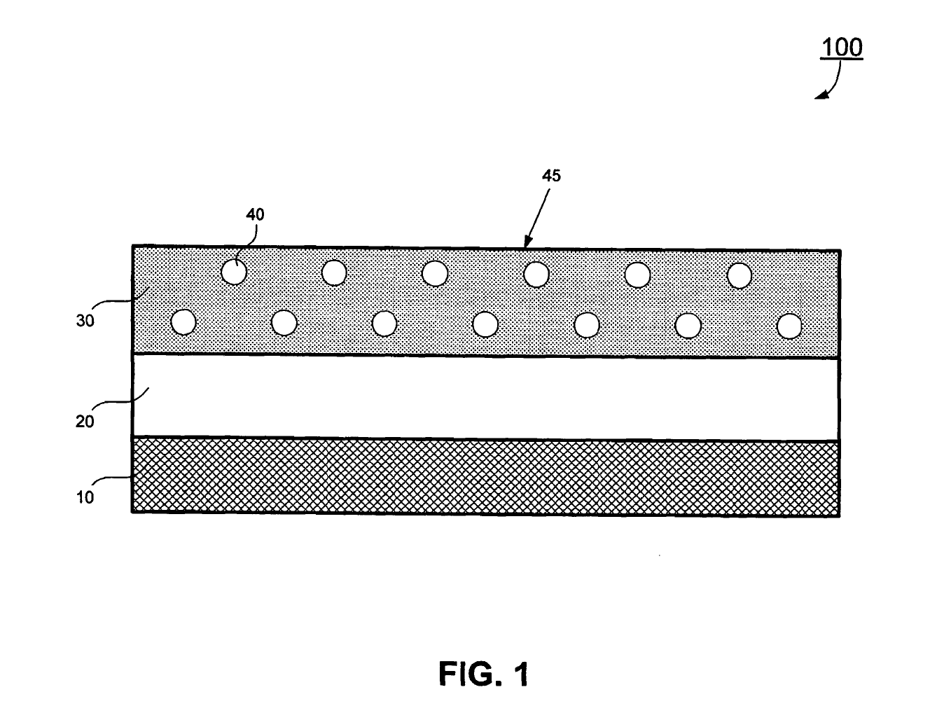

The description will be made as to the embodiments of the present invention in conjunction with the accompanying drawings in FIGS. 1-15. In accordance with the purposes of this invention, as embodied and broadly described herein, this invention relates to a layered structure 100 with laser-induced aggregation silicon nano-dots 40 in a silicon-rich dielectric layer 30, and its applications.

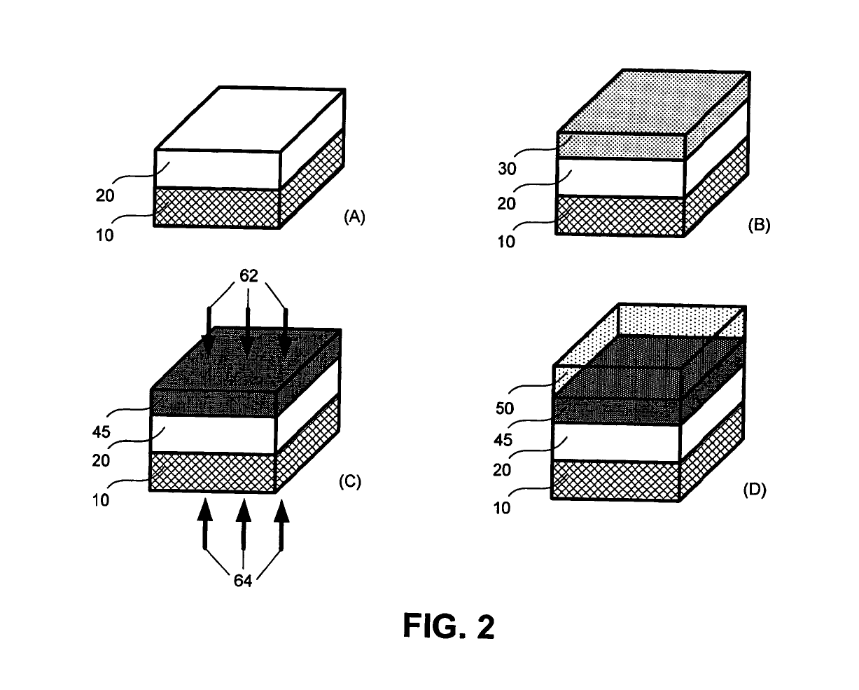

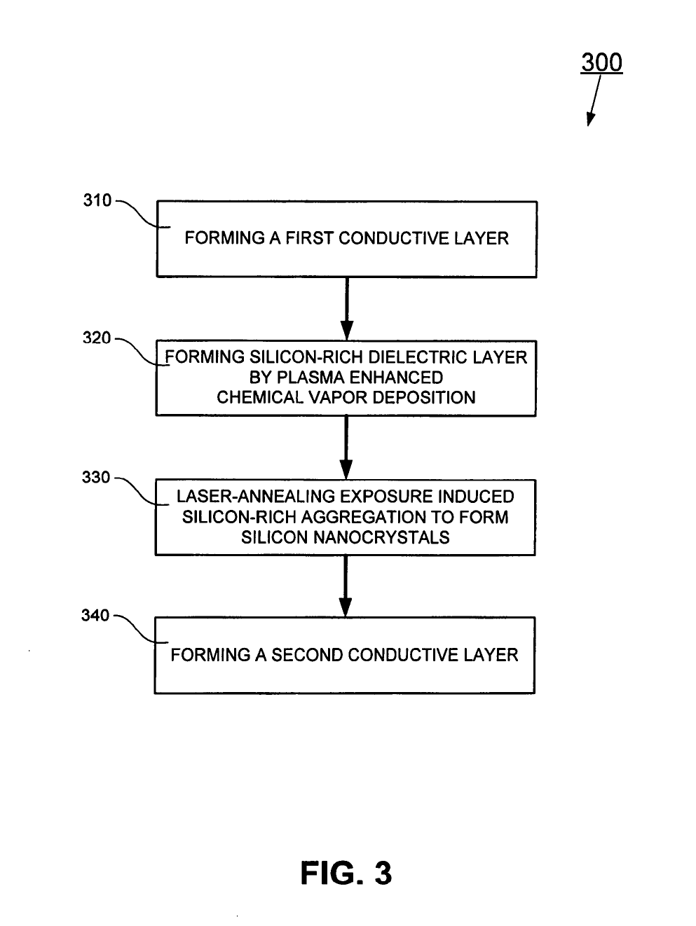

Referring first to FIGS. 1-3, an exemplary layered structure 100 with laser-induced aggregation silicon nano-dots 40 in a silicon-rich dielectric layer 30, and its forming process are illustrated according to one embodiment of the present invention. FIG. 1 shows a sectional view of a layered structure 100 with laser-induced aggregation silicon nano-dots 40 in a silicon-rich dielectric layer 30. The layered structure 100 has a substrate 10, a conductive layer 20, and a silicon-rich dielectric layer 30, and a plurality of laser-induced aggregation silicon nano-dots 40 in the silicon-rich dielectric layer 30. The silicon-rich dielectric layer with a plurality of laser-induced aggregation silicon nano-dots together is marked with numeral reference number 45. As shown in FIG. 2, an additional conductive layer 50 is formed on the silicon-rich dielectric layer 30. FIG. 3 shows a block diagram 300 corresponding to the process as illustrated in FIG. 2, illustrating how the layered structure 100 with laser-induced aggregation silicon nano-dots 40 in a silicon-rich dielectric layer 30 is formed.

In one embodiment as shown in FIGS. 2 and 3, a process of forming the layered structure 100 with laser-induced aggregation silicon nano-dots 40 in the silicon-rich dielectric layer 30 includes:

(i) forming a first conductive layer 20 on a substrate 10, at step 310 in FIG. 3;

(ii) forming a silicon-rich dielectric layer 30 on the first conductive layer 20, at step 320 in FIG. 3;

(iii) laser-annealing the silicon-rich dielectric layer 30 to induce silicon-rich aggregation in the layer 30 to form a plurality of laser-induced aggregation silicon nano-dots 40 in the silicon-rich dielectric layer 30, at step 330 in FIG. 3; and

(iv) forming a second conductive layer 50 on the silicon-rich dielectric layer 30, which now becomes the silicon-rich dielectric layer with laser-induced aggregation silicon nano-dots 45, at step 340 in FIG. 3.

These steps are not necessarily to be performed in sequence. Neither the process is the only way to practice the present invention.

In some embodiment, the substrate 10 is a transparent substrate (such as glass, quartz, or others materials), a flexible substrate (such as thinly glass, poly[ethylene-terephthalate] (PET), benzoCycloButane (BCB), polysiloxane, polyaniline, polymethyl methacrylate (PMMA), plastic, rubber, or other, or combinations thereof), or combinations thereof. In yet another embodiment, the substrate 10 can be a rigidity substrate (such as silicon wafer, ceramics, or others). Preferred, the substrate 10 is made of a non-semiconductor material (such as glass, quartz, ceramics, thinly glass, poly[ethylene-terephthalate] (PET), benzoCycloButane (BCB), polysiloxane, polyaniline, polymethyl methacrylate (PMMA), plastic, rubber, or other, or combinations thereof). In the embodiments of the present invention of the substrate is made of glass as an example, but not-limited thereto.

In one embodiment, the laser annealing is performed from the top of the layered structure as shown by laser beams 62 in FIG. 2C to be incident upon the silicon-rich dielectric layer 30. In another embodiment, the substrate 10 and the conductive layer 20 are made of transparent material such that the laser annealing is performed from the bottom of the layered structure as shown by laser beams 64 in FIG. 2C, and the laser beams 64 penetrate the substrate 10 and the conductive layer 20 to be incident upon the silicon-rich dielectric layer 30. In yet another embodiment, the laser annealing is performed from both the top and bottom of the layered structure as shown by laser beams 62 and laser beams 64 in FIG. 2C to reach the silicon-rich dielectric layer 30, respectively.

In one embodiment, a plurality of laser-induced aggregation silicon nano-dots is formed as a result of the laser annealing. In another embodiment, no laser-induced aggregation silicon nano-dots are formed as a result of the laser annealing. The first conductive layer 20 and the second conductive layer 50 may be formed with metal, metal oxide, or any combinations of these materials. The metal may be reflective materials comprise aluminum, copper, silver, gold, titanium, molybdenum, lithium, tantalum, neodymium, tungsten, alloy, others, or any combinations of these metals. The metal oxide may be transparent materials comprise indium tin oxide (ITO), indium zinc oxide (IZO), aluminum zinc oxide (AZO), hafnium oxide (HfO), others, or any combinations of these materials. The metal may be a combination of the reflective materials and the transparent materials. In some embodiment of at least one of the first conductive layer 20 and the second conductive layer 50 can be formed as a single layer or a multi-layer, the material of the single layer and one of the multi-layer can be used the above-mentioned materials.

In one embodiment, the silicon-rich dielectric layer 30 is a silicon-rich oxide film. In another embodiment, the silicon-rich dielectric layer 30 is a silicon-rich nitride film. In yet another embodiment, the silicon-rich dielectric layer 30 is silicon-rich oxy-nitride film. The silicon rich dielectric layer 30 can be formed as a single layer or a multi-layer structure. Either way, it contains at least one of the silicon-rich oxide film, the silicon-rich nitride film, and the silicon-rich oxy-nitride film.

The silicon-rich dielectric layer 30 is formed with a Plasma Enhanced Chemical Vapor Deposition (PECVD) process, at a low pressure of about 1 torr, at a temperature below about 400° C. In one embodiment, the silicon-rich dielectric layer 30 is formed at a temperature range of about 200° C. to about 400° C., or about 350° C. to about 400° C., preferably at a temperature of about 370° C. For the given temperature range, it takes about from 13 seconds to 250 seconds, preferably about 25 seconds to about 125 seconds, to form a silicon-rich dielectric layer 30 in a desirable thickness of about 50 nm to about 1000 nm. During the process of forming the silicon-rich dielectric layer 30, the refractive index of the silicon-rich dielectric layer 30 is controlled through adjusting the silicon content ratio SiH₄/N₂O. In one embodiment, the silicon content ratio SiH₄/N₂O is adjusted in the range of about 1:10 to about 1:1, resulting in a refractive index at least in the range of about 1.47 to about 2.3, the silicon content ratio is preferably in the range of about 1:5 to about 1:1, resulting in a refractive index at least in the range of about 1.7 to about 2.3. The silicon-rich dielectric layer can also be formed with other methods or processes.

In order to produce an effective photovoltaic device, the refractive index of the silicon-rich dielectric layer 30 preferably needs to be in a desirable range. In one embodiment, preferred, the silicon-rich oxide film has a refractive index in a range between about 1.47 and about 2.3. In another embodiment, , preferred, the silicon-rich nitride film has a refractive index in a range between about 1.7 and about 2.3.

The laser annealing the silicon-rich dielectric layer 30 can be done, for example by using excimer laser annealing (ELA). An excimer laser with an adjustable frequency and an adjustable laser power density at a temperature below 400° C. can be utilized. In one embodiment, the ELA is performed at a pressure of about 1 atm (760 torr), or about 1×e−3 Pa, and at a temperature below about 400° C. In another embodiment, the ELA is performed at a room temperature (i.e. about 20° C. to about 25° C., or about 68° F. to about 77° F.). Other types of laser annealing with corresponding parameters may also be utilized to practice the present invention.

The laser wavelength and the laser power level are adjustable to yield desirable diameters of the laser-induced aggregation silicon nano-dots. The laser wavelength is in a range of about 266 nm to about 1024 nm for any laser types such as, for examples, excimer laser annealing (ELA), continuous-wave laser crystallization (CLC), solid-state CW green laser, or others. The desirable diameters of the laser-induced aggregation silicon nano-dots are in the range of about 2 to about 10 nm, preferably in the range of about 3 to about 6 nm. In one embodiment, the ELA of the silicon-rich dielectric layer 30 is performed at a wavelength in the range of about 266 nm to about 532 nm, preferably about 308 nm. The ELA of the silicon-rich dielectric layer 30 is typically performed at a laser power density range of about 70 mJ/cm2 to 300 mJ/cm2, preferably at a laser power density range of 70 mJ/cm2 to about 200 mJ/cm2 (a current best range is of about 70 mJ/cm2 to about 200 mJ/cm2, of which there is no damage or laser peeling of the underlayer metal electrode). In other embodiment, the continuous-wave laser crystallization (CLC) of the silicon-rich dielectric layer 30 is performed at a wavelength in the range of, for example, about 532 nm to about 1024 nm. In another embodiment, the solid-state CW green laser of the silicon-rich dielectric layer 30 is performed at a wavelength of, for example, about 532 nm. However, when the laser power density exceeds about 200 mJ/cm2, the metal layer under the silicon-rich dielectric layer may be damaged, or peeled. In order to produce a silicon-rich dielectric layer with larger laser-induced aggregation silicon nano-dots in the range of about 4 nm to about 10 nm, the excimer laser annealing of the silicon-rich dielectric layer 30 is preferably performed at a laser power density range of about 200 mJ/cm2 to about 300 mJ/cm2. On the other hand, in order to produce a silicon-rich dielectric layer with smaller laser-induced aggregation silicon nano-dots in the range of about 2 to about 6 nm, the ELA of the silicon-rich dielectric layer 30 is preferably performed at a laser power density range of about 70 mJ/cm2 to about 200 mJ/cm2.

After the laser annealing step, the silicon-rich dielectric layer 30 becomes the silicon-rich dielectric layer 30 with a plurality of laser-induced aggregation silicon nano-dots 40. This silicon-rich dielectric layer with a plurality of laser-induced aggregation silicon nano-dots is now referred with numeral reference number 45 in FIGS. 2C and 2D. The density of the laser-induced aggregation silicon nano-dots 40 in the silicon-rich dielectric layer 30 is preferably in the range of about 1×1011/cm2 to about 1×1012/cm2. The silicon-rich dielectric layer can be further doped with N type, P type silicon, or combinations thereof.

After the silicon-rich dielectric layer 30 is annealed, a second conductive layer 50 may be formed on the silicon-rich dielectric layer with a plurality of laser-induced aggregation silicon nano-dots 45, as illustrated as step 340 in FIG. 3, and FIG. 2D. Such silicon nano-dots are also usable for non-volatile memory devices, where the laser-induced aggregation silicon nano-dots 40 are adapted to use as storage nodes for information storage. In another embodiment, the second conductive layer 50 can be a transparent layer, such as indium tin oxide (ITO) layer, indium zinc oxide (IZO), aluminum zinc oxide (AZO), hafnium oxide (HfO), others, or any combinations of these materials, reflective layer such as aluminum, copper, silver, gold, titanium, molybdenum, lithium, tantalum, neodymium, tungsten, alloy, others, or any combinations of these metals, or any combinations of these materials. In some embodiment of at least one of the first conductive layer 20 and the second conductive layer 50 can be formed as a single layer or a multi-layer, the material of the single layer and one of the multi-layer can be used the above-mentioned materials. Such a layered structure with a second conductive layer 50, which is made of a transparent material (such as ITO), is usable in a display (such as a liquid crystal display, electroluminescent display, others, or combinations of these displays). However, the second conductive layer 50 can also be a metal layer while the first conductive layer 20 is a transparent conductive layer, such as indium tin oxide (ITO) layer, indium zinc oxide (IZO), aluminum zinc oxide (AZO), hafnium oxide (HfO), others, or any combinations of these materials. The second conductive layer 50 also can be a transparent conductive layer, such as indium tin oxide (ITO) layer, indium zinc oxide (IZO), aluminum zinc oxide (AZO), hafnium oxide (HfO), other, or any combinations of these materials, while the first conductive layer 20 can be a metal layer. Both of the first conductive layer 20 and the second conductive layer 50 can be made from one of a transparent conductive layer and a thin metal layer that can permit light to pass through or both of the first conductive layer 20 and the second conductive layer 50 can be made a thin metal layer that can permit light to pass through.

When transparent conductive layers are used, the laser annealing can be performed before, or after the formation of the second conductive layer. The laser annealing can be performed from the top of the layered structure, from the bottom of the layered structure, or from both the top and the bottom of the layered structure.

Without intent to limit the scope of the invention, exemplary methods, devices and their related applications according to the embodiments of the present invention are given below. Note that titles or subtitles may be used in the examples for convenience of a reader, which in no way should limit the scope of the invention. Moreover, certain theories may be proposed and disclosed herein; however, in no way they, whether they are right or wrong, should limit the scope of the invention so long as the invention is practiced according to the invention without regard for any particular theory or scheme of action.

### EXAMPLE 1

### Solar Cell

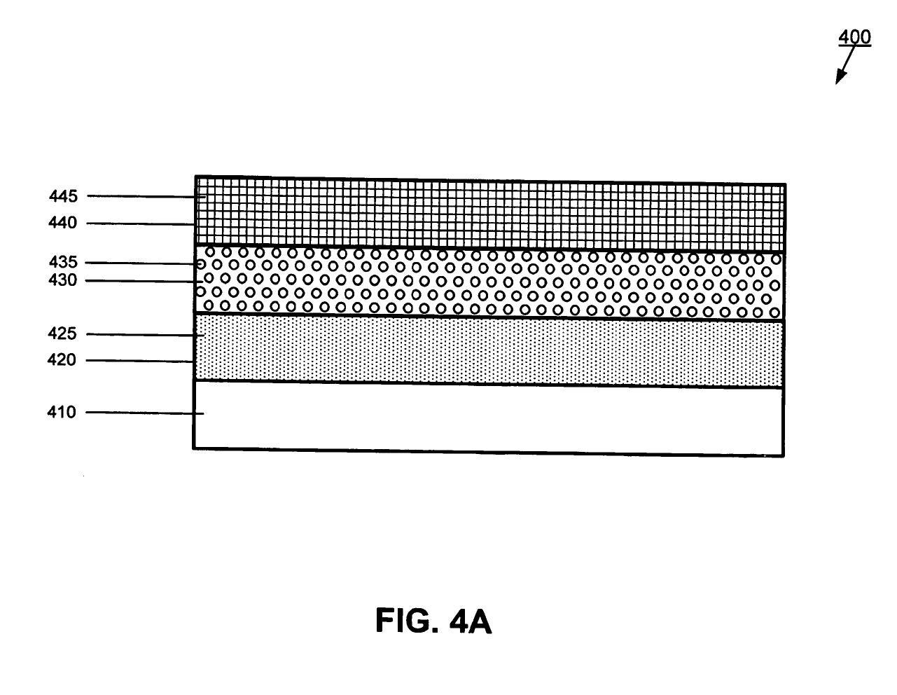

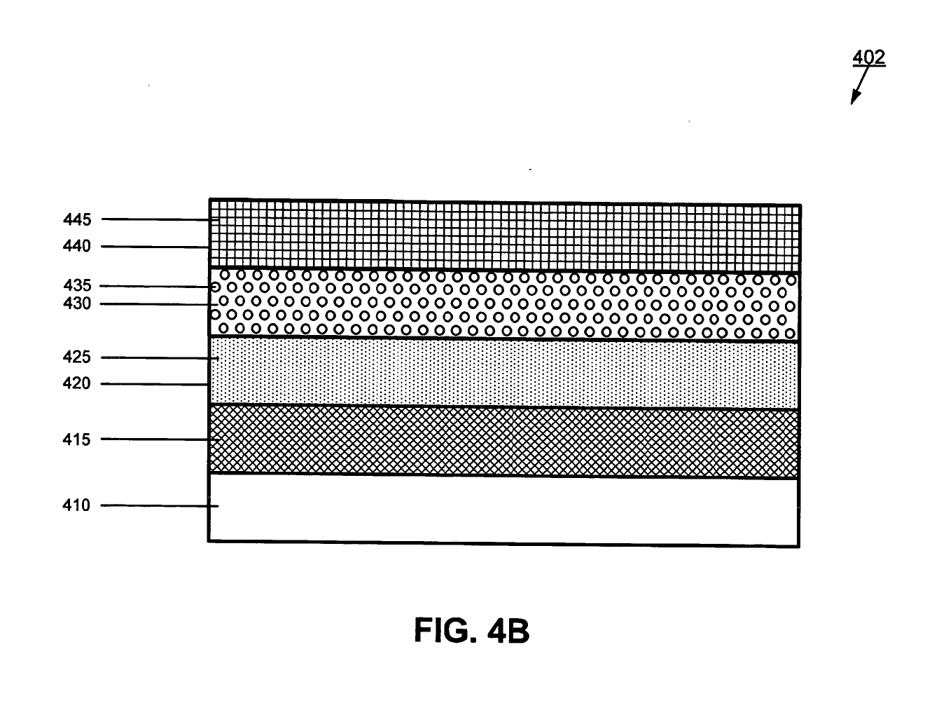

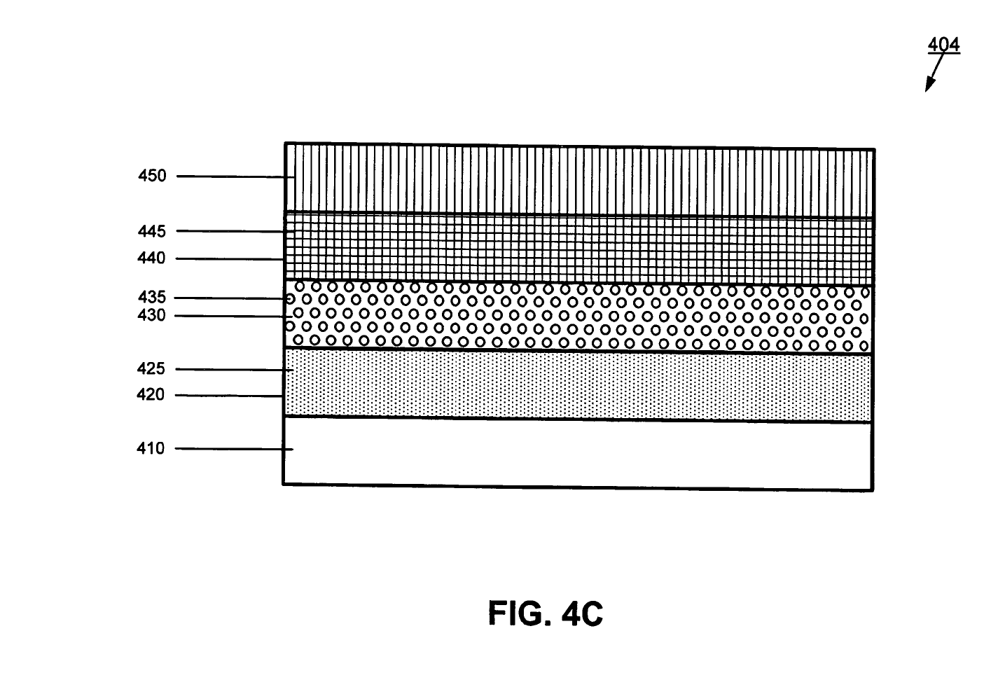

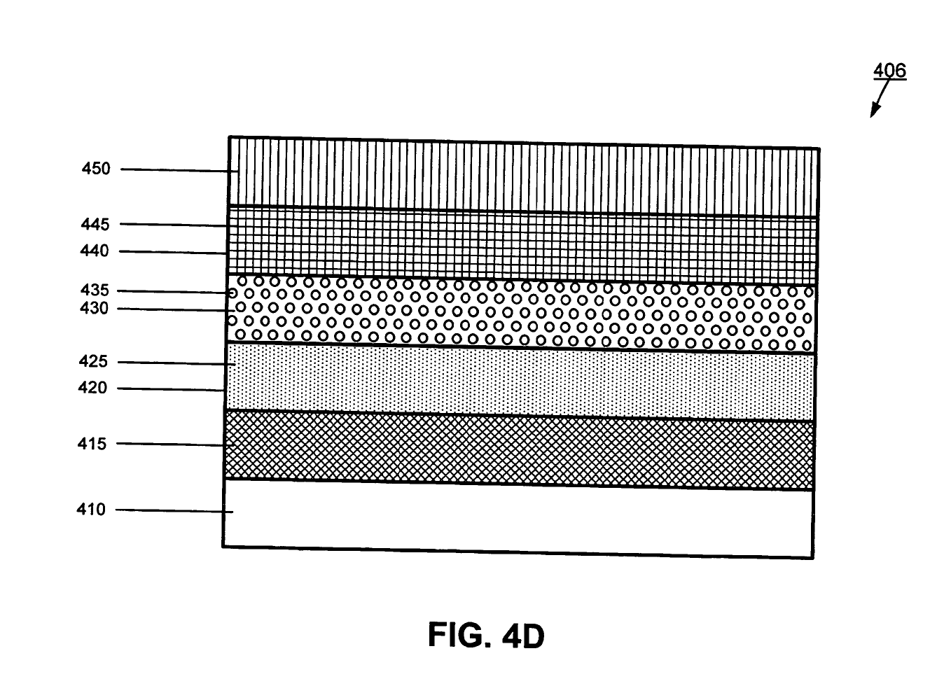

Referring to FIG. 4A, a sectional view of a solar cell 400 having laser-induced aggregation silicon nano-dots 435 in a silicon-rich dielectric layer 430 is shown according to one embodiment of the present invention. In one embodiment, the solar cell 400 has:

(i) a substrate 410;

(ii) a first semiconductor (such as a-Si) layer 420 formed on the substrate 410, where the first semiconductor (such as a-Si) layer 420 is then doped with n+ or p+ to form a first N-doped or P-doped semiconductor layer 425, correspondingly;

(iii) a silicon-rich dielectric layer 430 formed on the first N-doped or P-doped semiconductor layer 425, and having a plurality of laser-induced aggregation silicon nano-dots 435 that are formed by a laser-induced aggregation process; and

(iv) a second semiconductor (such as a-Si) layer 440 formed on the silicon-rich dielectric layer 430, where the second semiconductor (such as a-Si) layer 440 is then doped with p+ or n+ to form a second P-doped or N-doped doped semiconductor layer 445, correspondingly.

In one embodiment, the solar cell 402 further has a first conductive layer 415 (or namely a bottom conductive layer) formed between the substrate 410 and the first semiconductor layer 420, as shown in FIG. 4B. In another embodiment, the solar cell 404 further has a second conductive layer 450 (or namely a top conductive layer) formed on the second P-doped or N-doped semiconductor layer 445, as shown in FIG. 4C. In yet another embodiment, the solar cell 406 further has a first conductive layer 415 formed between the substrate 410 and the first semiconductor layer 420, and a second conductive layer 450 formed on the second P-doped or N-doped semiconductor layer 445, as shown in FIG. 4D.

The second conductive layer 450 is preferrably a transparent material layer that is made of transparent materials, such as indium tin oxide (ITO), indium zinc oxide (IZO), aluminum zinc oxide (AZO), hafnium oxide (HfO), others, or any combinations of these materials. It can also be made from reflective materials, such as Au, Ag, Cu, Fe, Sn, Pb, Cd, Ti, Ta, tungsten (W), Mo, Hf, Nd, others, or nitride thereof, or oxide thereof, or alloy, or combinations thereof. The second conductive layer 450 can also be made of combinations of the transparent material and reflective materials.

In one embodiment, the silicon-rich dielectric layer 430 includes silicon-rich oxide, silicon-rich nitride, silicon-rich oxy-nitride, silicon-rich carbide, or any combinations of these materials.

In one embodiment, at least one of the first semiconductor layer 420 and the second semiconductor layer 440 is an N-type semiconductor layer. In another embodiment, at least one of the first semiconductor layer 420 and the second semiconductor layer 440 is a P-type semiconductor layer. In yet another embodiment, at least one of the first semiconductor layer 420 and the second semiconductor layer 440 is a combination of both N-type semiconductor layer and P-type semiconductor layer.

In one embodiment, one of the first semiconductor layer 420 and the second semiconductor layer 440 is made of amorphous silicon, poly silicon, micro-crystallized silicon, mono-crystallized silicon, or any combinations of these materials. The laser crystallized N-type semiconductor and the laser crystallized P-type semiconductor are formed by a laser crystallization process.

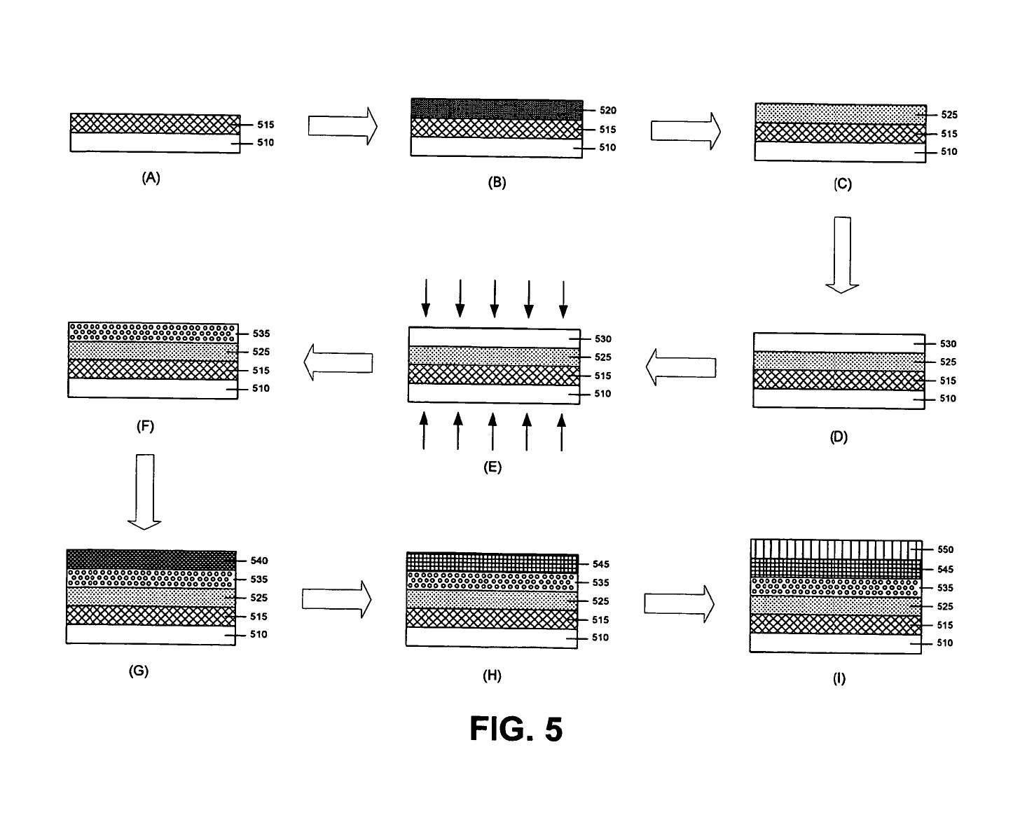

In one embodiment, the solar cell 400, which has a plurality of laser-induced aggregation silicon nano-dots 435 in a silicon-rich dielectric layer 430, is formed in a process as shown in FIG. 5. The process includes the steps of:

(i) providing a substrate 510;

(ii) forming a first semiconductor layer 520 on the substrate 510;

(iii) forming a first N-doped or P-doped semiconductor layer 525;

(iv) forming a silicon-rich dielectric layer 530 on the first N-doped or P-doped semiconductor layer 525;

(v) forming a plurality of laser-induced aggregation silicon nano-dots 535 by applying a laser-induced aggregation process on the silicon-rich dielectric layer 530;

(vi) forming a second semiconductor layer 540 on the silicon-rich dielectric layer 530 with a plurality of laser-induced aggregation silicon nano-dots 535; and

(vii) forming a second P-doped or N-doped semiconductor layer 545.

These steps can be performed in the order set forth above, or other alternative orders.

In one embodiment, the process further includes the step of forming a first conductive layer 515 between the substrate 510 and the first semiconductor layer 520. In one embodiment, the step of forming a first N-doped or P-doped semiconductor layer 525 includes the step of performing implantation process on the first semiconductor layer 520. In another embodiment, the step of forming a first N-doped or P-doped semiconductor layer 525 includes the step of applying in-situ plasma-CVD doping process on the first conductive layer 515.

In one embodiment, the second P-doped or N-doped semiconductor layer 545 is formed by performing an implantation process on the second semiconductor layer 540. In another embodiment, the second P-doped or N-doped semiconductor layer 545 is formed by in-situ plasma-CVD doping process on the silicon-rich dielectric layer 530 with a plurality of laser-induced aggregation silicon nano-dots 535.

In one embodiment, the laser-induced aggregation is performed from the top of the silicon-rich dielectric layer 530. In another embodiment, the laser-induced aggregation is performed from the bottom of the substrate 510 and the first N-doped or P-doped semiconductor layer 525 if the substrate 510 and the first N-doped or P-doped semiconductor layer 525 are transparent. In yet another embodiment, the laser-induced aggregation is performed both from the top of the silicon-rich dielectric layer 530, and from the bottom of the substrate 510 and the first N-doped or P-doped semiconductor layer 525. The power of the laser can be adjusted to penetrate the substrate 510 and the first N-doped or P-doped semiconductor layer 525 to reach the silicon-rich dielectric layer 530. The laser-induced aggregation can also be performed after step (G) after the second P-doped or N-doped semiconductor layer 545 is formed on the silicon-rich dielectric layer 530, if the second P-doped or N-doped semiconductor layer 545 is a transparent layer that allows laser beam or irradiation to pass through.

In one embodiment, the process further includes the step of forming a second conductive layer 550 on the second semiconductor layer 540. The second conductive layer 550 is preferably a transparent material layer that is made of transparent materials, such as indium tin oxide (ITO), indium zinc oxide (IZO), aluminum zinc oxide (AZO), hafnium oxide (HfO), others, or any combinations of these materials. It can also be made from reflective materials, such as Au, Ag, Cu, Fe, Sn, Pb, Cd, Ti, Ta, Nd, tungsten (W), Mo, Hf, others, or nitride thereof, or oxide thereof, or alloy, or combinations thereof. The second conductive layer 550 can also be made of combinations of the transparent material and reflective materials.

In one embodiment, the silicon-rich dielectric layer 530 of the solar cell is made of materials such as silicon-rich oxide, silicon-rich nitride, silicon-rich oxy-nitride, silicon-rich carbide, or any combinations of these materials. In one embodiment, the bottom-electrode layer 515 is formed on the substrate 510. In one embodiment, the substrate 510 as formed is a transparent substrate such as a glass substrate. In another embodiment, the substrate 510 as formed is a flexible substrate such as a plastic substrate.

In one embodiment, at least one of the first semiconductor layer 520 and the second semiconductor layer 540 is made of amorphous silicon, poly silicon, micro-crystallized silicon, mono-crystallized silicon, or any combinations of these materials. At least one of the first semiconductor layer 520 and the second semiconductor layer 540 is made of an N-type semiconductor, a P-type semiconductor, a laser crystallized N-type semiconductor, a laser crystallized P-type semiconductor, or any combinations of these materials. The laser crystallized N-type semiconductor and the laser crystallized P-type semiconductor can be formed by a laser crystallization process.

In one embodiment, at least one of the substrate 510, the first semiconductor layer 520, and the second semiconductor layer 540 is made of transparent material, opaque material, reflective material, or any combinations of these materials. During the laser crystallization process, laser irradiation is delivered to at least one of the first semiconductor layer 520 and the second semiconductor layer 540 along any desired directions through one or more transparent layers. In one embodiment, during the laser-induced aggregation process, the laser irradiation is delivered to and incident upon the silicon-rich dielectric layer 530 along any desired directions through one or more transparent layers.

The present invention in one aspect relates to another method for forming a solar cell. In one embodiment, the method includes:

(i) providing a substrate 510;

(ii) forming a multi-layer structure with at least two layers on the substrate 510, wherein each layer of the multi-layer structure has a first state and a second state; and

(iii) irradiating a laser beam to the multi-layer structure to allow at least one layer of the multi-layer structure to change from the first state to the second state.

The first state of each layer of the multi-layer structure has a non-crystallized state. At least one layer of the multi-layer structure has a plurality of laser-induced aggregation silicon nano-dots, and is at a corresponding second state which has a substantially non-crystallized state. The second state of at least two layers of the multi-layer structure can be a substantially crystallized state, a substantially micro-crystallized state, or a non-crystallized state. The substantially crystallized state or a substantially micro-crystallized state is caused by a laser crystallization process.

In one embodiment, the method further includes the step of forming a first conductive layer between the substrate and the multi-layer structure. In another embodiment, the method further includes the step of forming a second conductive layer on the multi-layer structure. At least one of the substrate 510, one or more layers of the multi-layer structure, the first conductive layer, and the second conductive layer is made of a transparent material, opaque material, reflective material, or any combinations of these materials. The laser beam is delivered to the multi-layer structure along any desired directions through one or more transparent layers.

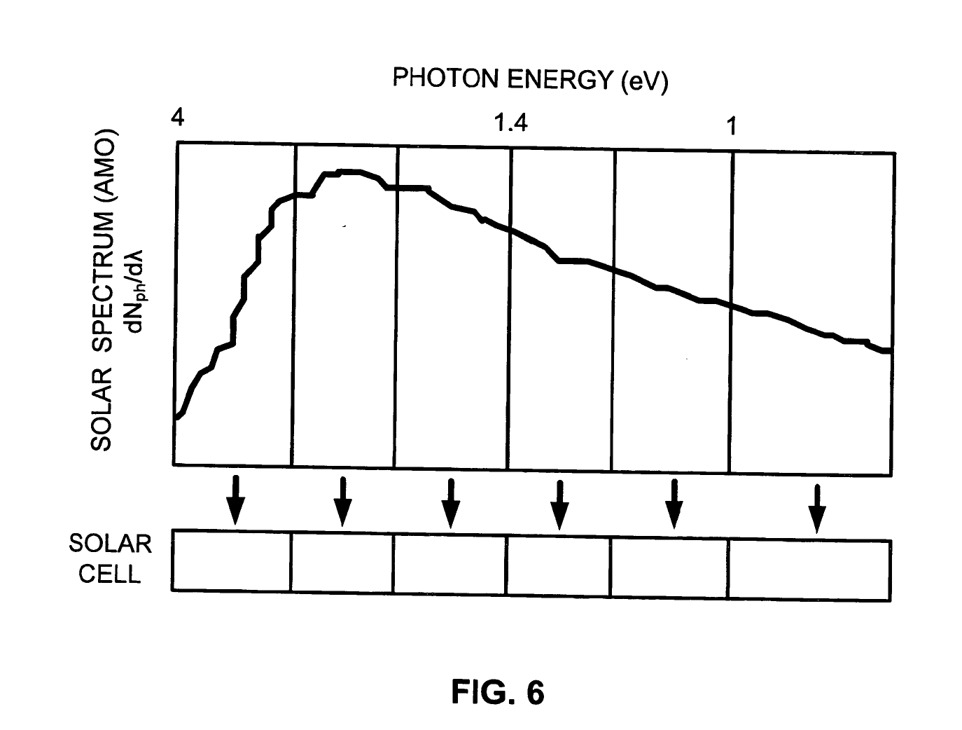

In one aspect of this invention, the multiple-bandgap Si nanocrystals solar cell (with single junction) is made to replace a multiple-junction device having a stack of individual single-junction cells in descending order of bandgap. In the multiple-junction cell device, the top cell captures the high-energy photons and passes the rest of the photons on to be absorbed by lower-bandgap cell. Due to the variations of melting temperature of different semiconductor materials and their energy absorption efficiency levels, a plurality of laser-induced aggregation silicon nano-dots can also be formed by laser crystallizing polycrystalline silicon or amorphous silicon films. Therefore, the laser crystallization process constructs a multi-bandgap light absorption structure. This multi-bandgap light absorption structure can be integrated into a high efficiency solar cell. FIG. 6 demonstrates that a multi-band gap spectrum for a solar cell according to the present invention is divided into multiple narrow regions. In this embodiment, the photons in each region with band-gap tuned for that region are converted to produce high-efficiency solar cell.

### EXAMPLE 2

### Nonvolatile Memory Element

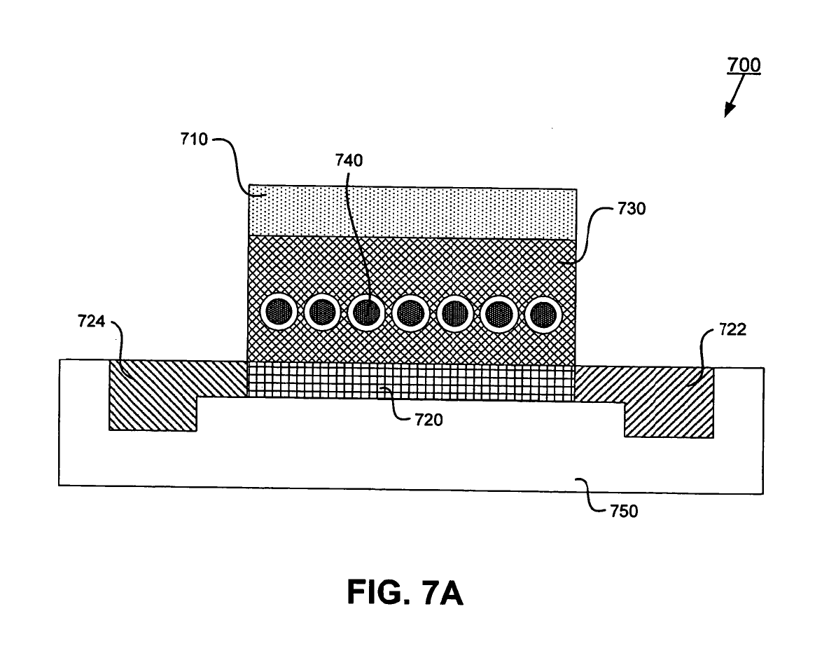

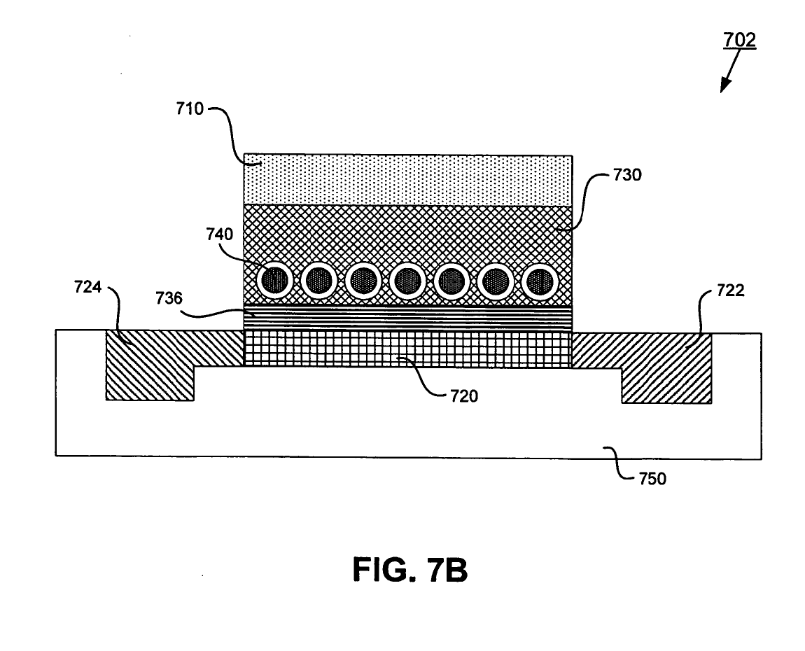

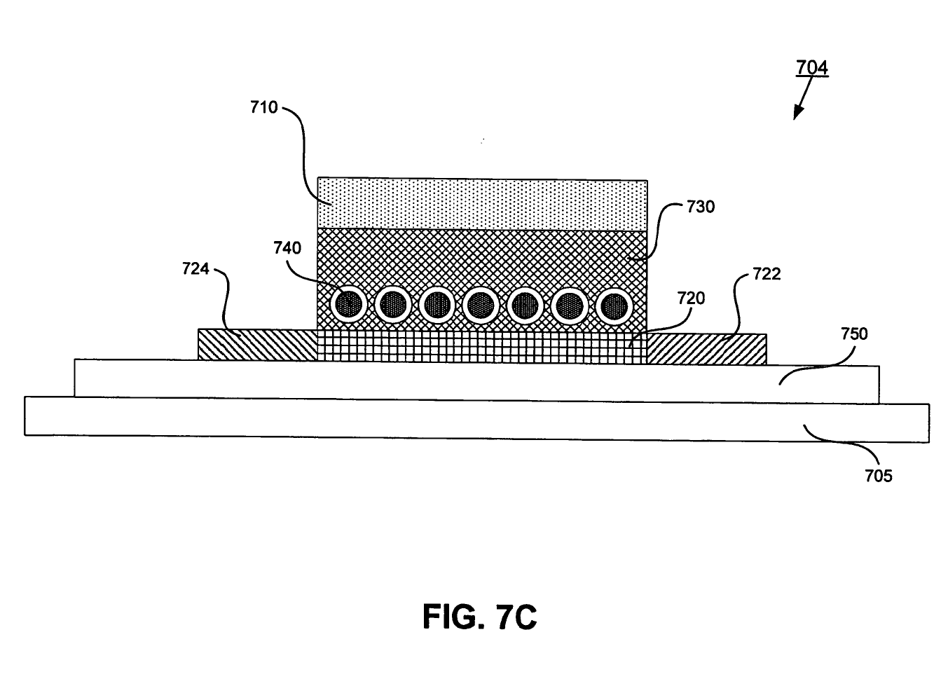

Referring to FIG. 7A, a nonvolatile memory element 700 having the laser-induced aggregation silicon nano-dots in a silicon-rich dielectric layer is shown according to one embodiment of the present invention. In one embodiment, the nonvolatile memory element 700 has:

(i) a conductive layer 710;

(ii) a semiconductor layer 750;

(iii) a silicon-rich dielectric layer 730 having a plurality of laser-induced aggregation silicon nano-dots 740 between the conductive layer 710 and the semiconductor layer 750;

(iv) a drain region 722 formed in the semiconductor layer 750;

(v) a source region 724 formed in the semiconductor layer 750; and

(vi) a channel region 720 formed between the drain region 722 and the source region 724. The channel region 720 has direct contact with the silicon-rich dielectric layer 730.

The plurality of laser-induced aggregation silicon nano-dots 740 is formed by laser-annealing the silicon-rich dielectric layer 730 as set forth above. In one embodiment, a source electrode (not shown) is formed on the source region 724, and a drain electrode (not shown) is formed on the drain region 722, respectively.

In one embodiment, the conductive layer 710 as the gate electrode of the nonvolatile memory element 700 is made of transparent material, opaque material, reflective material, or any combinations of these materials. Transparent materials such as indium tin oxide (ITO), indium zinc oxide (IZO), aluminum zinc oxide (AZO), hafnium oxide (HfO), others, or any combinations of these materials can be used to form the conductive layer 710, which is transparent accordingly. In one embodiment, the thickness of the silicon-rich dielectric layer 730 is about 30 to about 50 nm, but not-limited thereof. A plurality of laser-induced aggregation silicon nano-dots 740 is formed and distributed in the silicon-rich dielectric layer 730. The laser-induced aggregation silicon nano-dots 740 are formed in a region, which is located between about 2 nm to about 5 nm above the bottom surface of the silicon-rich dielectric layer 730, and between about 6 nm to about 10 nm below the top surface of the silicon-rich dielectric layer 730. The laser-induced aggregation silicon nano-dots 740, preferred, are about 2 nm to about 6 nm in diameters.

In one embodiment, the semiconductor layer 720 is formed on a substrate 750, and is made of amorphous silicon, poly silicon, micro-crystallized silicon, mono-crystallized silicon, or any combinations of these materials. The semiconductor layer 720 includes an N-type semiconductor, a P-type semiconductor, a laser crystallized N-type semiconductor, a laser crystallized P-type semiconductor, or any combinations of these materials. The laser crystallized N-type semiconductor and the laser crystallized P-type semiconductor are formed by a laser crystallization process.

In another embodiment, the silicon-rich dielectric layer 730 can be made of silicon-rich oxide, silicon-rich nitride, silicon-rich oxy-nitride, silicon-rich carbide, or any combinations of these materials. At least one of the substrate 750, the semiconductor layer 720, and the conductive layer 710 is made of transparent material, opaque material, reflective material, or any combinations of these materials.

In one embodiment, the semiconductor layer 720 of the nonvolatile memory element 700 is a laser crystallized N-type silicon layer. In another embodiment, the semiconductor layer 720 of the nonvolatile memory element 700 is a laser crystallized P-type silicon layer. In one embodiment, a source electrode (not shown) is formed on the source region 724, a drain electrode (not shown) is formed on the drain region 722, respectively, and connected to other device(s), such as signal line, capacitor, switch, power line, etc.

In another embodiment, a nonvolatile memory element 702 having laser-induced aggregation silicon nano-dots 740 in a silicon-rich dielectric layer 730 is shown in FIG. 7B. In this embodiment, the nonvolatile memory element 702 has:

(i) a conductive layer 710;

(ii) a semiconductor layer 750;

(iii) a silicon-rich dielectric layer 730 having a plurality of laser-induced aggregation silicon nano-dots 740 between the conductive layer 710 and the semiconductor layer 750;

(iv) a drain region 722 formed in the semiconductor layer 750;

(v) a source region 724 formed in the semiconductor layer 750;

(vi) a channel region 720 formed between the drain region 722 and the source region 724; and

(vii) a tunnel dielectric layer 736 formed between the channel region 720 and the silicon-rich dielectric layer 730.

The plurality of laser-induced aggregation silicon nano-dots 740 is formed by laser-annealing the silicon-rich dielectric layer 730 as set forth above. In one embodiment, a source electrode is (not shown) formed on the source region 724, a drain electrode (not shown) is formed on the drain region 722, respectively, and connected to other device(s), such as signal line, capacitor, switch, power line, etc.

In one embodiment, the semiconductor layer 720 is formed on a substrate 750, and is made of amorphous silicon, poly silicon, micro-crystallized silicon, mono-crystallized silicon, or any combinations of these materials. The semiconductor layer 720 can be made of an N-type semiconductor, a P-type semiconductor, a laser crystallized N-type semiconductor, a laser crystallized P-type semiconductor, or any combinations of these materials. The laser crystallized N-type semiconductor and the laser crystallized P-type semiconductor are formed by a laser crystallization process.

The silicon-rich dielectric layer 730 can be made of silicon-rich oxide, silicon-rich nitride, silicon-rich oxy-nitride, silicon-rich carbide, or any combinations of these materials.

In one embodiment, the semiconductor layer 720 of the nonvolatile memory element 700 is a laser crystallized N-type silicon layer. In another embodiment, the semiconductor layer 720 of the nonvolatile memory element 700 is a laser crystallized P-type silicon layer. In one embodiment, a source electrode (not shown) is formed on the source region 724, a drain electrode (not shown) is formed on the drain region 722, respectively, and connected to other device(s), such as signal line, capacitor, switch, power line, etc.

In yet another embodiment, a nonvolatile memory element 704 having laser-induced aggregation silicon nano-dots in a silicon-rich dielectric layer is shown in FIG. 7C. In this embodiment, the nonvolatile memory element 704 has:

(i) a conductive layer 710;

(ii) a buffer dielectric layer 750 on a substrate 705;

(iii) a semiconductor layer 720 is formed on the buffer dielectric layer 750;

(iv) a silicon-rich dielectric layer 730 having a plurality of laser-induced aggregation silicon nano-dots 740 between the conductive layer 710 and the semiconductor layer 720;

(v) a drain region 722 formed in the semiconductor layer 720;

(vi) a source region 724 formed in the semiconductor layer 720; and

(vii) a channel region 760 formed between the drain region 722 and the source region 724. The channel region 760 has direct contact with the silicon-rich dielectric layer 730.

The buffer dielectric layer 750 is made of inorganic material (such as silicon nitride, silicon oxide, silicon oxy-nitride, silicon carbide, others, or combinations thereof), organic material (such as poly[ethylene-terephthalate] (PET), benzoCycloButane (BCB), polysiloxane, polyaniline, polymethyl methacrylate (PMMA), plastic, rubber, or other, or combinations thereof), or combinations thereof. In some embodiment, the buffer dielectric layer 720 cans be as a single layer or multi-layer, and the single layer or one of the multi-layer is made of the above-mentioned materials. In the present embodiments, the buffer dielectric layer 750 is an inorganic material, such as silicon oxide or silicon nitride as an example. In other embodiment, the nonvolatile memory element 704 can be not formed the buffer dielectric layer 750 on the substrate 705. The plurality of laser-induced aggregation silicon nano-dots 740 is formed by laser-annealing the silicon-rich dielectric layer 730 as set forth above. In one embodiment, a source electrode (not shown) is formed on the source region 724, and a drain electrode (not shown) is formed on the drain region 722, respectively.

In one embodiment, a source electrode (not shown) is formed on the source region 724, a drain electrode (not shown) is formed on the drain region 722, respectively, and connected to other device(s), such as signal line, capacitor, switch, power line, etc.

The memory element 704 has a configuration similar to that of the nonvolatile memory element 702. Yet, it does not have the tunnel dielectric layer 736, and the substrate is a glass substrate.

In additional, the above-mentioned embodiment is used a top-gate type structure in the FIGS. 7, but not-limited thereto, the bottom-gate type structure is can be used in the present invention.

The present invention in another aspect relates to a method for forming a nonvolatile memory element. In one embodiment, the method includes:

(i) providing a semiconductor layer 720 having a source region 724 and a drain region 722;

(ii) forming a silicon-rich dielectric layer 730 on the semiconductor layer 720;

(iii) applying a laser beam incident upon the silicon-rich dielectric layer 730 to form a plurality of laser-induced aggregation silicon nano-dots 740 in the silicon-rich dielectric layer 730; and

(iv) forming a conductive layer 710 on the silicon-rich dielectric layer 730.

The method may include one or more of the following steps:

(i) providing a source electrode and a drain electrode electrically coupled to the source region 724 and the drain region 722, respectively; and/or

(ii) forming a tunnel dielectric layer 736 between the semiconductor layer 720 and the silicon-rich dielectric layer 730; and/or

(iii) providing a buffer dielectric layer 750 on the glass substrate 705 to allow the semiconductor layer 720 to be formed on the buffer dielectric layer 750.

These steps can be performed in the order set forth above or other alternative orders.

The conductive layer 710 is made of transparent conductive material, opaque material, reflective conductive material, or any combinations of these materials. The semiconductor layer 720 is made of amorphous silicon, poly silicon, micro-crystallized silicon, mono-crystallized silicon, or any combinations of these materials.

The semiconductor layer 720 can be formed as an N-type semiconductor, a P-type semiconductor, a laser crystallized N-type semiconductor, a laser crystallized P-type semiconductor, or any combinations of them. The laser crystallized N-type semiconductor and the laser crystallized P-type semiconductor are formed by a laser crystallization process.

In one embodiment, at least one of the substrate 750, the semiconductor layer 720, and the conductive layer 710 is made of transparent material, opaque material, reflective material, or any combinations of these materials. During the laser crystallization process, the laser irradiation is delivered to the semiconductor layer 720 along any desired directions through one or more transparent layers. During the laser-induced aggregation process, the laser irradiation is delivered to the silicon-rich dielectric layer 730 along any desired directions through one or more transparent layers.

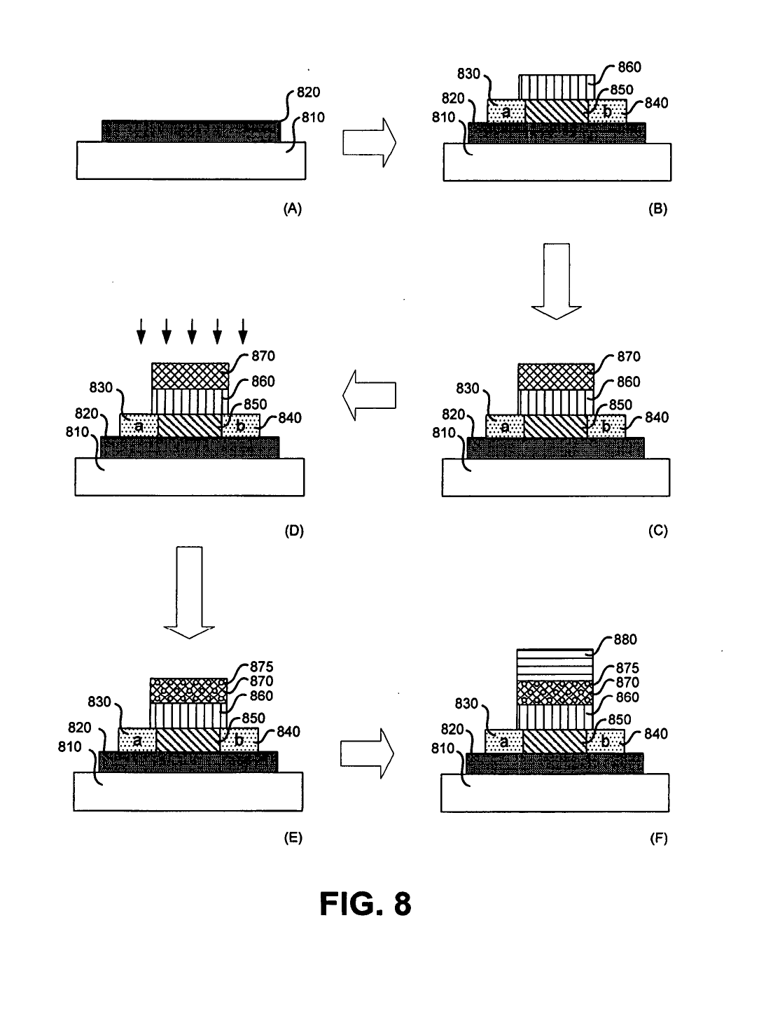

A nonvolatile memory element may be alternatively formed by a process with following steps, as shown in FIG. 8:

(i) providing a buffer dielectric layer 820 on a substrate 810;

(ii) providing a poly-Si semiconductor layer on the buffer dielectric layer 820, wherein a source region (n+, or p+) 830, an intrinsic channel region (n-channel, or p-channel) 850, and a drain region (n+, or p+) 840 are formed in the semiconductor layer, respectively;

(iii) providing a tunnel dielectric layer 860 on the poly-Si semiconductor layer;

(iv) forming a silicon-rich dielectric layer 870 on the tunnel dielectric layer 860;

(v) forming a plurality of laser-induced aggregation silicon nano-dots 875 by applying a laser-induced aggregation process on the silicon-rich dielectric layer 870, and

(vi) forming a conductive layer (as a control gate) 880 on the silicon-rich dielectric layer 870 with the plurality of laser-induced aggregation silicon nano-dots 875.

In step (v), in one embodiment, a laser is used to perform the laser-induced aggregation from the top of the silicon-rich dielectric layer 870. The laser-induced aggregation can also be performed after step (vi) after the conductive layer 880 is formed on the silicon-rich dielectric layer 870, if the conductive layer 880 is a transparent layer.

At least one of the buffer dielectric layer 820 and the tunnel dielectric layer 860 comprises an inorganic material (such as silicon nitride, silicon oxide, silicon oxy-nitride, silicon carbide, others, or combinations thereof), an organic material (such as poly[ethylene-terephthalate] (PET), benzoCycloButane (BCB), polysiloxane, polyaniline, polymethyl methacrylate (PMMA), plastic, rubber, or other, or combinations thereof), or combinations thereof. In some embodiment, at least one of the buffer dielectric layer 820 and the tunnel dielectric layer 860 can be as a single layer or multi-layer, and the single layer or one of the multi-layers is made of the above-mentioned materials. In the present embodiments, the buffer dielectric layer 820 is the inorganic material, such as silicon oxide or silicon nitride, and the tunnel dielectric layer 860 is the inorganic material, such as silicon oxide as an example.

In one embodiment, at least one of the buffer dielectric layer 820 and the tunnel dielectric layer 860 can be not provided.

In one embodiment, the conductive layer 880 of the nonvolatile memory element has a transparent layer that is made of indium tin oxide (ITO), indium zinc oxide (IZO), aluminum zinc oxide (AZO), hafnium oxide (HfO), others, or any combinations of these materials. The conductive layer 880 of the nonvolatile memory element can be made of other materials. In one embodiment, a gate electrode is connected with the conductive layer 880.

In one embodiment, the silicon-rich dielectric layer 870 is made of materials such as silicon-rich oxide, silicon-rich nitride, silicon-rich oxy-nitride, silicon-rich carbide, or any combinations of these materials. In one embodiment, the substrate 810 is formed as a transparent substrate such as a glass substrate. In another embodiment, the substrate 810 is formed as a flexible substrate such as a plastic substrate.

In one embodiment, the semiconductor layer is made of amorphous silicon, poly silicon, micro-crystallized silicon, mono-crystallized silicon, or any combinations of these materials.

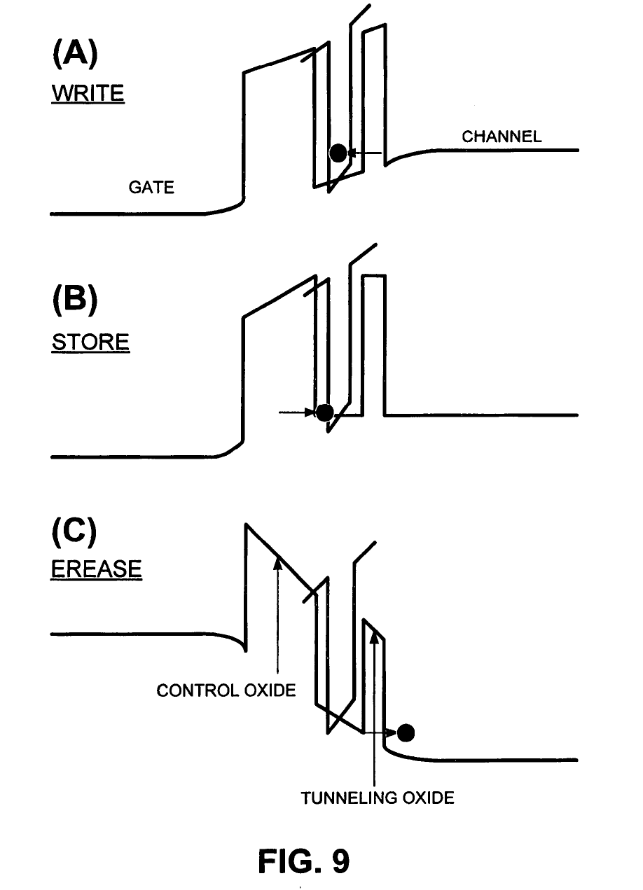

FIGS. 9A to 9C respectively show the band-gap curves when electrons tunneling quantum dots to deep energy band of laser-induced aggregation silicon nano-dots (A) to write, (B) to store, and (C) to erase information in the nonvolatile memory element according to embodiments of the present invention.

### EXAMPLE 3

### Photo Sensitive Element

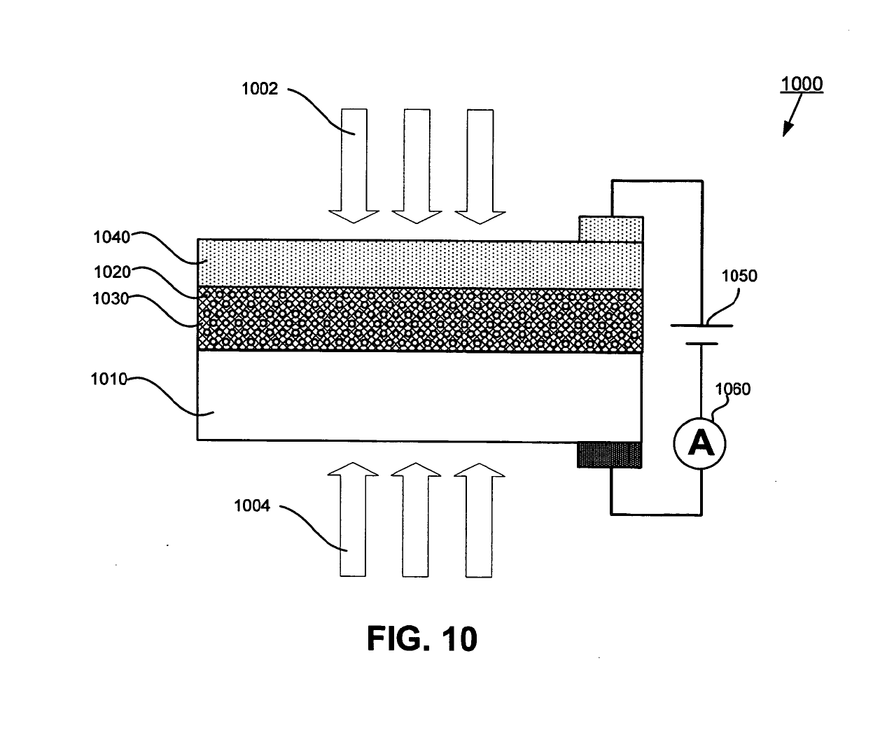

Referring to FIG. 10, a photo sensitive element 1000 having a plurality of laser-induced aggregation silicon nano-dots in a silicon-rich dielectric layer is partially shown according to one embodiment of the present invention. The photo sensitive element 1000 has:

(i) a first conductive layer 1010;

(ii) a second conductive layer 1040; and

(iii) a silicon-rich dielectric layer 1030 having a plurality of laser-induced aggregation silicon nano-dots 1020 and formed between the first conductive layer 1010 and the second conductive layer 1040.

The plurality of laser-induced aggregation silicon nano-dots 1020 of the photo sensitive element 1000 is formed by laser-annealing the silicon-rich dielectric layer 1030 as set forth above. The second conductive layer 1040 is transparent to allow visible light such as laser beam to reach the silicon-rich dielectric layer 1030 of the photo sensitive elements 1000. In one embodiment, the first conductive layer 1010 of the photo sensitive element 1000 is made from reflective materials, such as Au, Ag, Cu, Fe, Sn, Pb, Cd, Ti, Ta, Nd, tungsten (W), Mo, Hf, others, or nitride thereof, or oxide thereof, or alloy, or combinations thereof. In one embodiment, the second conductive layer 1040 of the photo sensitive element 1000 is formed as a transparent layer that is made of transparent materials, such as indium tin oxide (ITO) layer, indium zinc oxide (IZO), aluminum zinc oxide (AZO), hafnium oxide (HfO), others, or any combinations of these materials. However, the second conductive layer 1040 of the photo sensitive element 1000 can be made from reflective materials, such as Au, Ag, Cu, Fe, Sn, Pb, Cd, Ti, Ta, Nd, tungsten (W), Mo, Hf, others, or nitride thereof, or oxide thereof, or alloy, or combinations thereof.

The silicon-rich dielectric layer 1030 includes a plurality of laser-induced aggregation silicon nano-dots 1020. The silicon-rich dielectric layer 1030 is made of silicon-rich oxide, silicon-rich nitride, silicon-rich oxy-nitride, silicon-rich carbide, or any combinations of these materials.

In one embodiment, the first conductive layer 1010 is formed on a substrate. At least one of the first conductive layer 1010, the second conductive layer 1040 and the substrate is made of transparent material, opaque material, reflective material, or any combinations of these materials.

One or more such photo sensitive elements can be utilized to form a photo detector. The photo sensitive element can also be used as photo sensor, light sensor light detector, finger-print sensor, ambient light sensor, and display panel. The display panel can be used in a touch panel.

In an illustrative example, as shown in FIG. 10, battery 1050 stores an electronic potential generated by exposing the photo sensitive elements 1000 to visible lights 1002 and 1004, and ammeter 1060 is used to measure the corresponding current generated by the photo sensitive element 1000. In one embodiment, the silicon-rich dielectric layer 1030 of the photo sensitive element 1000 is made of materials such as silicon-rich oxide, silicon-rich nitride, silicon-rich oxy-nitride, silicon-rich carbide, or any combinations of these materials.

In one aspect of the present invention, a method of forming photo sensitive element 1000 includes the steps of:

(i) providing a first conductive layer 1010;

(ii) forming a silicon-rich dielectric layer 1030 on the first conductive layer 1010;

(iii) laser annealing the silicon-rich dielectric layer 1030 to form a plurality of laser-induced aggregation silicon nano-dots 1020 in the silicon-rich dielectric layer 1030; and

(iv) forming a second conductive layer 1040 on the silicon-rich dielectric layer 1030 with the plurality of laser-induced aggregation silicon nano-dots 1020.

In one embodiment, the method further includes the step of providing a substrate to allow the first conductive layer to be formed on the substrate. At least one of the first conductive layer 1010, the second conductive layer 1040, and the substrate is made of transparent material, opaque material, reflective material, or any combinations of these materials. In one embodiment, the silicon-rich dielectric layer is made of silicon-rich oxide, silicon-rich nitride, silicon-rich oxy-nitride, silicon-rich carbide, or any combinations of these materials. During the laser-induced aggregation process, the laser irradiation from a laser is delivered to the silicon-rich dielectric layer along any desired directions through one or more transparent layers.

These steps are not necessarily to be performed in sequence. Neither the process is the only way to practice the present invention. These steps may be performed in alternative orders. In one embodiment, the first conductive layer of the photo sensitive element is a metal layer. In another embodiment, both the first conductive layer 1010 and the second conductive layer 1040 of the photo sensitive element 1000 are formed as transparent layers that are made of transparent materials, such as indium tin oxide (ITO) layer, indium zinc oxide (IZO), aluminum zinc oxide (AZO), hafnium oxide (HfO), others, or any combinations of these materials. However, the first conductive layer 1010 and the second conductive layer 1040 of the photo sensitive element 1000 can be made of other materials.

In one embodiment, the silicon-rich dielectric layer 1030 of the photo sensitive element 1000 is made of materials such as silicon-rich oxide, silicon-rich nitride, silicon-rich oxy-nitride, silicon-rich carbide, or any combinations of these materials.

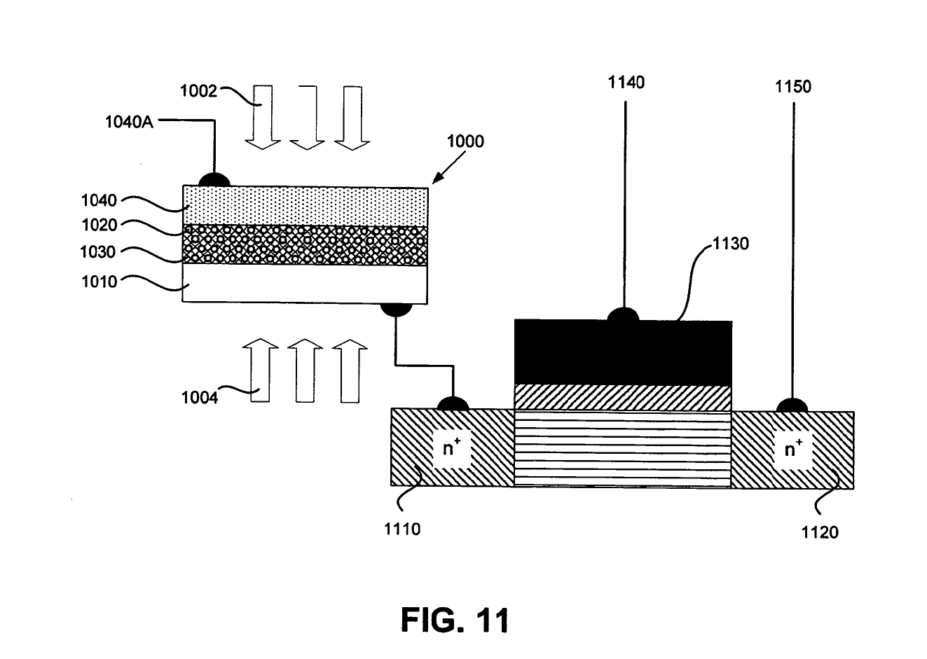

FIG. 11 shows schematically an application of a photo sensitive element 1000 having laser-induced aggregation silicon nano-dots 1020 in a silicon-rich dielectric layer 1030 in conjunction with a readout thin film transistor (TFT) according to one embodiment of the present invention. As shown in FIG. 10, the photo sensitive element has a first conductive layer 1010 formed on a substrate, a silicon-rich dielectric layer 1030 having a plurality of laser-induced aggregation silicon nano-dots 1020, and a second conductive layer 1040. The readout thin film transistor (TFT) has a highly doped N type silicon source region 1110, a highly doped N type silicon drain region 1120, a gate electrode 1130, and a dielectric layer (not shown) formed between the gate electrode, the highly doped N type silicon source region 1110, and a highly doped N type silicon drain region 1120. The photo sensitive element 1000 is used as a photo diode, with its second conductive layer 1040 electrically coupled, through connecting wire 1040A, to the ground of an electric circuit (not shown), and its first conductive layer 1010 electrically coupled to the source region 1110 of the readout thin film transistor (TFT). The gate electrode 1130 is coupled to one part of an electronic circuit (not shown) through its connecting wire 1140 and the drain region 1120 is connected to another part of the electronic circuit through its connecting wire 1150. The gate electrode 1130 and drain region 1120 are electrically coupled through connecting wire 1140 and 1150, respectively, to other parts of an electronic circuit.

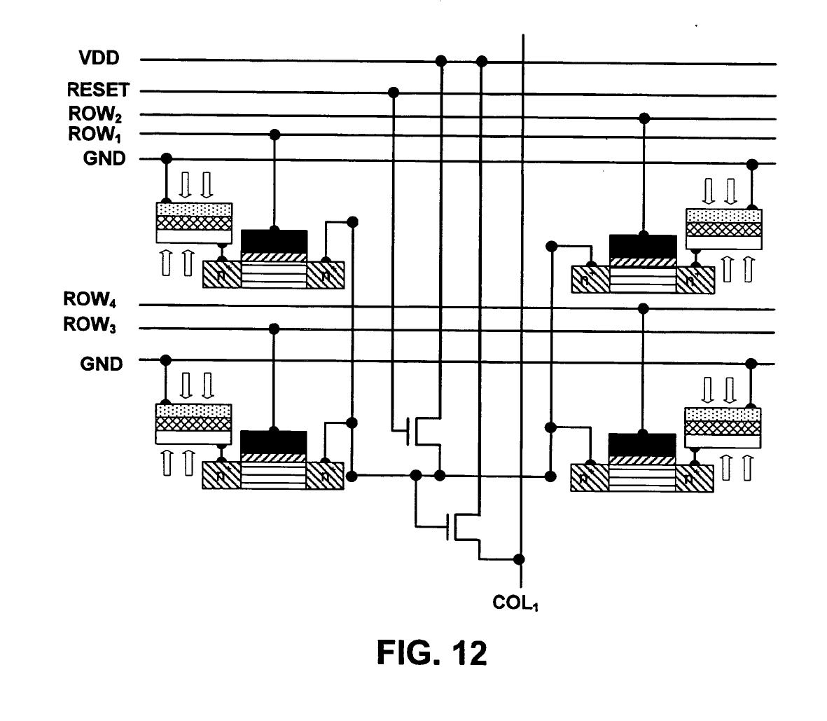

FIG. 12 shows a portion of a shared electronic circuit having multiple photo sensitive elements having laser-induced aggregation silicon nano-dots in a silicon-rich dielectric layer according to one embodiment of the present invention. In FIG. 12, only four photo sensitive elements are shown. Usually, the photo sensitive elements are arranged in an N×M matrix form to form a photo sensor, or a photo detector having N×M photo sensitive elements, where N, M are nonzero integers. In this exemplary circuit, the power supply VDD, ground GND, and reset input RESET are shared by all photo sensitive elements. Each row and each column share their own input to corresponding rows, ROW₁, ROW₂, . . . ROW_{N}, and corresponding columns COL₁, COL₂, . . . , COL_{M}, respectively.

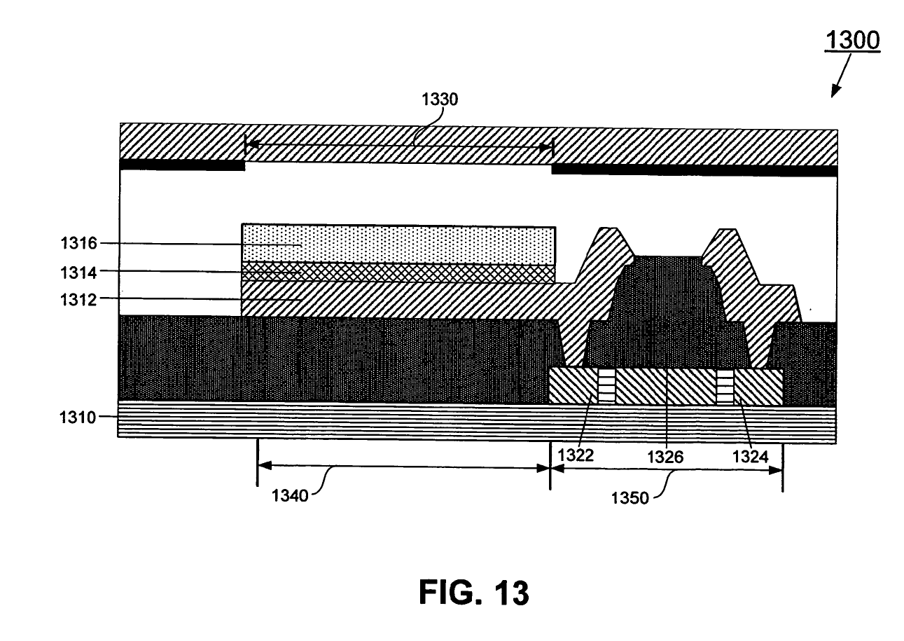

FIG. 13 shows a sectional view of a readout thin film transistor and a photo sensitive element having laser-induced aggregation silicon nano-dots in a silicon-rich dielectric layer integrated into a low temperature polycrystalline silicon (LTPS) panel 1300 according to one embodiment of the present invention. At a first portion 1340 of the photo sensitive element, a photo sensitive element is formed with a first conductive layer 1312, a silicon-rich dielectric layer 1314 having a plurality of laser-induced aggregation silicon nano-dots, and a second conductive layer 1316. At the second portion 1350 of the photo sensitive element, a readout thin film transistor (TFT) is formed on a substrate 1310 with a source region 1322, a drain region 1324, and a gate electrode 1326.

The first conductive layer 1312 is a metal layer in this embodiment, which is used to electrically couple with the source region 1322 of the readout TFT. The second conductive layer 1316 is a transparent conductive layer allowing visible light to pass through to reach the silicon-rich dielectric layer 1314 with laser-induced aggregation silicon nano-dots. The gate electrode 1326 and drain region 1324 are electrically coupled to other parts (not shown) of the circuit. A window 1330 defined on the top of the photo sensitive element to allow light to pass through, which is called fill factor in the art.

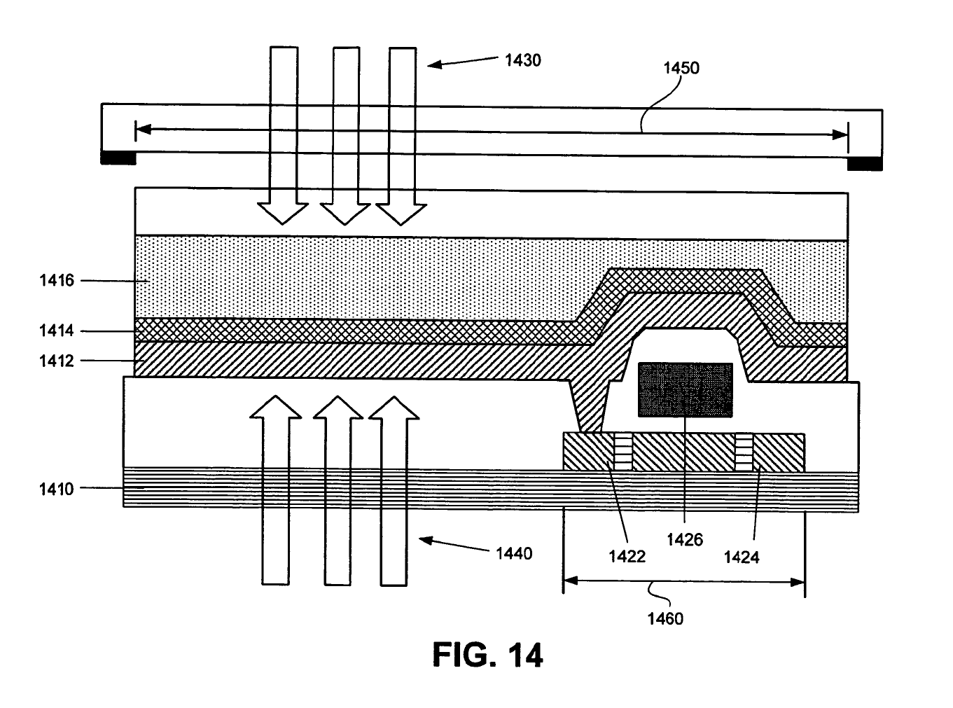

Another embodiment of the integration of photo sensitive elements into LTPS panel is shown in FIG. 14, which has a wider fill factor. In FIG. 14, a photo sensitive element has a three-layer stacked structure on a readout TFT. A photo sensitive element is formed to have a first conductive layer 1412, a silicon-rich dielectric layer 1414 having a plurality of laser-induced aggregation silicon nano-dots, and a second conductive layer 1416. The fill factor of this photo sensitive element is enlarged by the three layers of the photo sensitive element to cover a larger area. The readout TFT has a source region 1422, which is electrically coupled to the first conductive layer 1412 of the photo sensitive element, a drain region 1424 and a gate electrode 1426. The readout TFT is formed on a substrate 1410. In one embodiment, the substrate 1410 is formed as a transparent substrate such as a glass substrate. In another embodiment, the substrate 1410 is formed as a flexible substrate such as a plastic substrate. When such a photo sensitive element is utilized in a display panel, the photo sensitive element is configured to face an ambient light 1430. On the other hand, backlight 1440 is usually used to display information on the display panel. In order to prevent the backlight from biasing output of the photo sensitive element, the first conductive layer 1412 is utilized to effectively block the backlight.

The present invention in another aspect also relates to a layered structure with a plurality of laser-induced aggregation silicon nano-dots in a silicon-rich dielectric layer. In one embodiment, the layered structure has:

(i) a substrate;

(ii) a first conductive layer formed on the substrate; and

(iii) a silicon-rich dielectric layer formed on the first conductive layer, wherein the silicon-rich dielectric layer has a plurality of laser-induced aggregation silicon nano-dots.

In one embodiment, the silicon-rich dielectric layer is made of silicon-rich oxide, silicon-rich nitride, silicon-rich oxy-nitride, silicon-rich carbide, or any combinations of these materials. The silicon-rich oxide layer, preferred, has a refractive index in the range of about 1.47 to about 2.3, and the silicon-rich nitride layer, preferred, has a refractive index in the range of about 1.7 to about 2.3. At least some of the silicon nano-dots, preferred, have diameters ranging from about 2 nm to about 10 nm.

In the layered structure, the thickness of the silicon-rich dielectric layer is in the range of about 50 to about 1000 nm. The density of the laser-induced aggregation silicon nano-dots, preferred, range from about 1×10¹¹/cm² to about 1×10¹²/cm². In one embodiment, the layered structure also includes a second conductive layer. At least one of the first conductive layer and second conductive layer is made of transparent material, opaque material, reflective material, or any combinations of these materials.

The layered structure can be utilized in a solar cell, a photo sensitive element, and a display panel. The display panel can further be used in a touch panel. Moreover, the layered structure can be used in a non-volatile memory device, where at least some of the plurality of laser-induced aggregation silicon nano-dots is used as storage nodes.

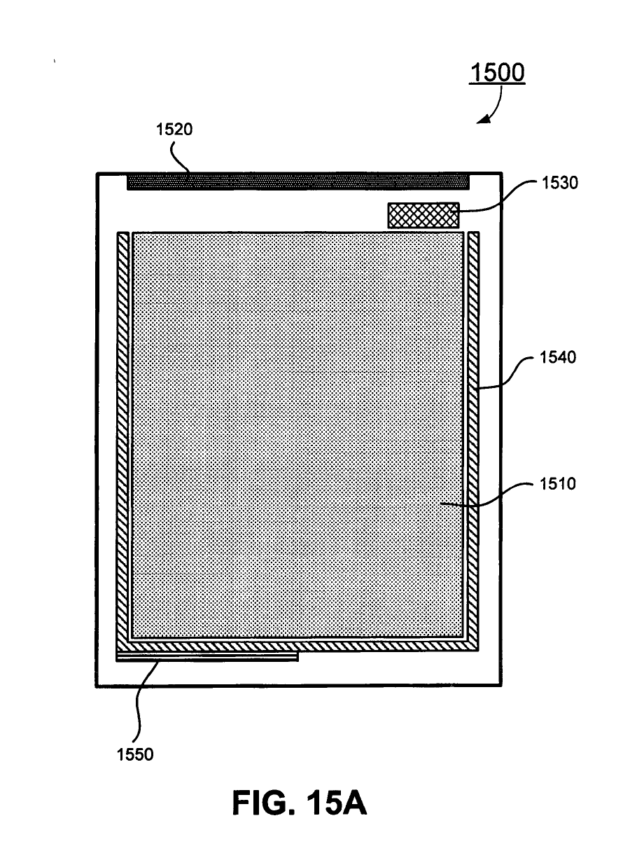

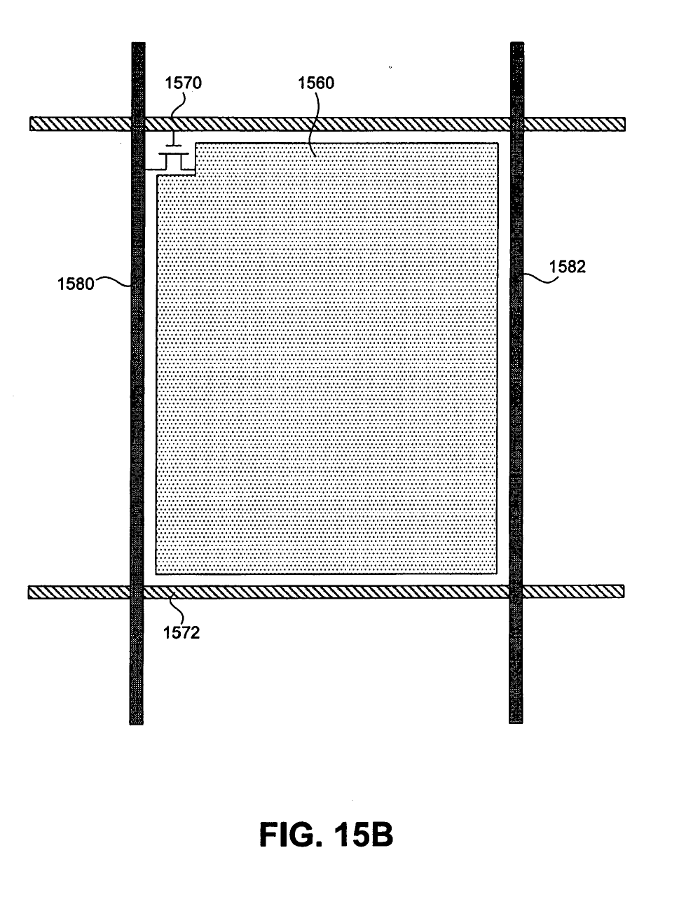

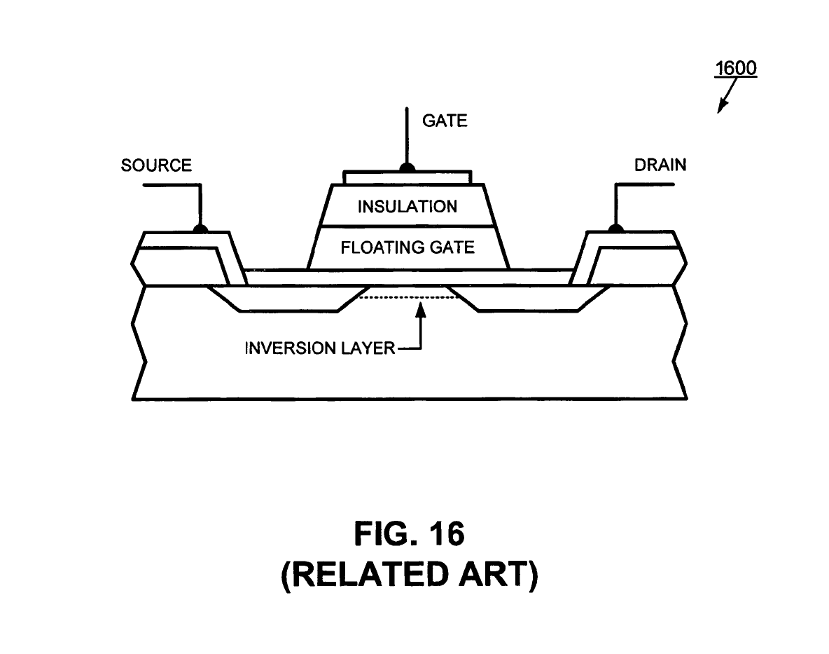

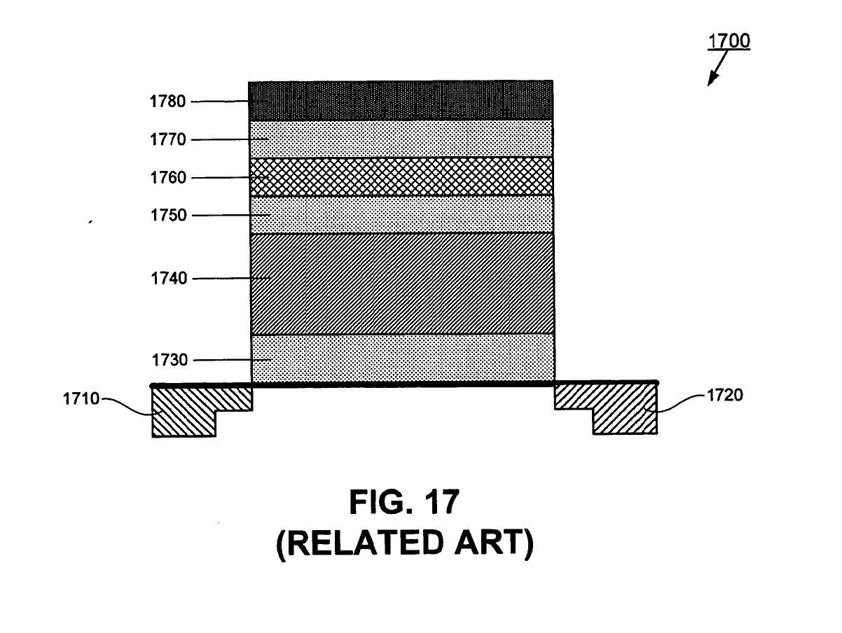

One or more of photo sensitive elements may be used to form a photo detector, a photo sensor, a touch panel, and/or a display panel having touch control capability. In FIG. 15, according to one embodiment of the present invention, a display panel 1500 is shown. The display panel 1500 includes (i) a display area 1510 for displaying information, (ii) a display area 1520 for transferring information and receiving user input, (iii) a photo detector 1530 for detecting light, (iv) a solar cell 1540 for converting solar energy to power, and (v) an ambient light sensor 1550 for detecting ambient light, all of them having at least one silicon-rich dielectric layer with laser-induced aggregation silicon nano-dots. The exemplary display panel 1500 has a rectangular shape. The width of the display panel 1500, preferred, is about 38 mm, and the height of the display panel 1500 is about 54 mm.

In a first embodiment, the display panel 1500 has a display area 1510 for display information. In the non-display area, the display panel has at least one photo detector 1530 for detecting light, a solar cell 1540 for converting solar energy to power, and an ambient light sensor 1550 for detecting ambient light. The photo detector 1530 and the ambient light sensor 1550 can be positioned in any corner area to detect ambient light or other light. The solar cell 1540 can be positioned around the display area 1510 to convert the light received therein into electric energy to save energy consumed by the display panel 1500.

In a second embodiment, the display panel 1500 has a display area 1510 for display information and receiving user's control signal, which is a touch panel alone.

In a third embodiment, the display panel 1500 has a display area 1510 for display information and receiving user's control signals and a non-display area. At least one of a photo detector 1530 for detecting light, a solar cell 1540 for converting solar energy to power, and an ambient light sensor 1550 for detecting ambient light is positioned in the non-display area. The photo detector 1530 and the ambient light sensor 1550 can be positioned in any corner area to detect ambient light or other light. The solar cell 1540 is positioned around the display area 1510 to convert the light received therein into electric energy to save energy consumed by the display panel 1500.

In a fourth embodiment, the display panel 1500 has at least one of a display area for display information, and a display area for display information and receiving user's control. The display panel 1500 has also a photo detector 1530 for detecting light, a solar cell 1540 for converting solar energy to power, and an ambient light sensor 1550 for detecting ambient light. The photo detector 1530 and the ambient light sensor 1550 can be positioned anywhere in display area 1510 to detect ambient light or other light. The solar cell 1540 can be embedded anywhere in the display area 1510 to convert the light on the surface of the display panel 1500 into electric energy to save energy consumed by the display panel 1500.

Other combinations of these components of the display panel are also possible without departing from the teachings of the present invention.

The display area 1510 with photo sensitive elements arranged in a matrix form can be used to detect user controls on the surface of the display panel. This display panel 1500, of course, only illustrates one exemplary application of technology developed according to the present invention.

FIG. 15B illustrates one of a plurality of pixels in the display area 1510 shown in FIG. 15A. Each of the plurality of pixels in the display area 1510 has at least a display area 1560, a scan line 1570, and a data line 1580. The scan line 1572 is for an adjacent pixel. The data line 1582 is also for another adjacent pixel. Each pixel includes at least one of a display pixel, a touch panel pixel, a photo detector 1530, a solar cell 1540 and an ambient light sensor 1550. The plurality of the pixels can be arranged in an N×M matrix to form a large display panel, touch panel, with any or all of the functionalities of the photo detector 1530, the solar cell 1540 and the ambient light sensor 1550.

The methods disclosed in the present invention may be used to manufacture photovoltaic layer for light emitting devices, and/or photosensitive layer for light detection devices, with a high efficiency laser annealing process at low temperature. The laser-induced aggregation silicon nano-dots in the dielectric layer made according to embodiments of the present invention exhibit a high density, quite uniform and consistent distribution of the laser-induced aggregation silicon nano-dots, and consistent diameters of the laser-induced aggregation silicon nano-dots. The methods disclosed in several embodiments of the present invention use excimer laser annealing process at a low temperature. This process does not require high temperature post annealing and is compatible with the conventional process to produce low temperature polysilicon thin film transistor (LTPS TFT). The silicon-rich dielectric layer with laser-induced aggregation silicon nano-dots manufactured according to several embodiments of the present invention is usable for solar cells, touch panels, ambient light sensor, photodetectors, and also integrable with a full color high quality TFT flat panel display. The laser-induced aggregation silicon nano-dots quantum dots manufactured according to several embodiments of the present invention is also usable as a storage node in non-volatile memory devices, with higher retention, higher endurance and higher operating speed.

The foregoing description of the exemplary embodiments of the invention has been presented only for the purposes of illustration and description and is not intended to be exhaustive or to limit the invention to the precise forms disclosed. Many modifications and variations are possible in light of the above teaching. For example, whenever an ITO layer is used to practice the present invention, an IZO layer may be used as an alternative, and vice versa.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A solar cell, comprising:
a. a substrate;
b. a bottom-conductive layer formed on the substrate;
c. a first semiconductor layer, formed on the bottom-conductive layer, wherein the first semiconductor layer is doped with n+ or p+ to form a first N-doped or P-doped semiconductor layer;
d. a silicon-rich dielectric layer having a plurality of laser-induced aggregation silicon nano-dots, wherein the silicon-rich dielectric layer is formed on the first N-doped or P-doped semiconductor layer;
e. a second semiconductor layer on the silicon-rich dielectric layer, wherein the second semiconductor layer is doped with p+ or n+ to form a second P-doped or N-doped semiconductor layer; and
f. a top-conductive layer formed on the second P-doped or N-doped semiconductor layer.

2. The solar cell of claim 1, wherein the silicon-rich dielectric layer comprises silicon-rich oxide, silicon-rich nitride, silicon-rich oxy-nitride, silicon-rich carbide, or any combinations thereof.

3. A method for forming a solar cell, comprising:
a. providing a substrate;
b. forming a bottom-conductive layer on the substrate;
c. forming a first semiconductor layer on the bottom-conductive layer;
d. doping the first semiconductor layer to form a first N-doped or P-doped semiconductor layer;
e. forming a silicon-rich dielectric layer on the first N-doped or P-doped semiconductor layer;
f. forming a plurality of laser-induced aggregation silicon nano-dots by applying a laser beam incident upon the silicon-rich dielectric layer;
g. forming a second semiconductor layer on the silicon-rich dielectric layer with a plurality of laser-induced aggregation silicon nano-dots; and
h. doping the second semiconductor layer to form a second P-doped or N-doped semiconductor layer.

4. The method of claim 3, further comprising the step of forming a top conductive layer on the second semiconductor layer.

5. A method for forming a solar cell, comprising:
a. providing a substrate;
b. forming a multi-layer structure with at least two layers on the substrate, wherein each layer of the multi-layer structure has a first state and a second state; and
c. irradiating a laser beam to the multi-layer structure to allow at least one layer of the multi-layer structure to change from the first state to the second state.

6. The method of claim 5, wherein the first state of each layer of the multi-layer structure comprises a non-crystallized state.

7. The method of claim 5, wherein at least one layer of the multi-layer structure has a plurality of laser-induced aggregation silicon nano-dots, and is at a corresponding second state that comprises a substantially non-crystallized state.

8. The method of claim 5, wherein the second state of at least two layers of the multi-layer structure comprises a substantially crystallized state, a substantially micro-crystallized state, or a non-crystallized state.

9. The method of claim 5, further comprising the step of forming a first conductive layer between the substrate and the multi-layer structure.

10. The method of claim 9, further comprising the step of forming a second conductive layer on the multi-layer structure.

11. A nonvolatile memory element, comprising:
a. a substrate;
b. a semiconductor layer having a source region, which is n+ or p+, and a drain region, which is n+ or p+;
c. a charged storage layer is a silicon-rich dielectric layer formed on the semiconductor layer, and having a plurality of laser-induced aggregation silicon nano-dots; and
d. a conductive layer is formed on the charged storage layer as a control gate.

12. The nonvolatile memory element of claim 11, further comprising a buffer dielectric layer formed between the semiconductor layer and the substrate.

13. The nonvolatile memory element of claim 11, further comprising a source electrode and a drain electrode electrically coupled to the source region and the drain region, respectively.

14. The nonvolatile memory element of claim 13, further comprising a tunnel dielectric layer formed on the substrate.

15. A method for forming a nonvolatile memory element, comprising:
a. providing a substrate;
b. providing a semiconductor layer on the a substrate, wherein a source region that is n+ or p+, an intrinsic channel region that is an n-channel or p-channel, and a drain region that is n+ or p+, are formed in the semiconductor layer, respectively;
c. forming a silicon-rich dielectric layer on the tunnel dielectric layer;
d. forming a plurality of laser-induced aggregation silicon nano-dots by applying a laser-induced aggregation process on the silicon-rich dielectric layer; and
e. forming a conductive layer as a control gate on the silicon-rich dielectric layer with the plurality of laser-induced aggregation silicon nano-dots.

16. The method of claim 14, further comprising the step of providing a source electrode electrically coupled to the source region and a drain electrode electrically coupled to the drain region, respectively.

17. The method of claim 14, further comprising the step of providing a buffer dielectric layer between the substrate and the semiconductor layer.

18. The method of claim 16, further comprising the step of providing a tunnel dielectric layer on the semiconductor layer.

19. A photo sensitive element, comprising:
a. a first conductive layer;
b. a second conductive layer; and
c. a silicon-rich dielectric layer, formed between the first conductive layer and the second conductive layer, and having a plurality of laser-induced aggregation silicon nano-dots.

20. The photo sensitive element of claim 19, wherein the first conductive layer is formed on a substrate.

21. A photo detector comprising one or more of photo sensitive elements of claim 19.

22. A display panel comprising one or more of photo sensitive elements of claim 19.

23. A touch panel comprising a display panel of claim 22.

24. A method for forming a photo sensitive element, comprising:
a. providing a first conductive layer;
b. forming a silicon-rich dielectric layer on the first conductive layer;
c. applying a laser-induced aggregation process to the silicon-rich dielectric layer to form a plurality of laser-induced aggregation silicon nano-dots in the silicon-rich dielectric layer; and
d. forming a second conductive layer on the silicon-rich dielectric layer.

25. The method of claim 24, further comprising the step of providing a substrate such that the first conductive layer is formed on the substrate.

26. The method of claim 24, wherein during the laser-induced aggregation process, the laser irradiation is delivered to the silicon-rich dielectric layer along any desired directions through one or more transparent layers.

27. A layered structure, comprising:
a. a substrate;
b. a first conductive layer formed on the substrate; and
c. a silicon-rich dielectric layer formed on the first conductive layer, wherein the silicon-rich dielectric layer has a plurality of laser-induced aggregation silicon nano-dots.

28. The layered structure of claim 27, wherein the silicon-rich oxide layer has a refractive index in the range of about 1.47 to about 2.3, and wherein the silicon-rich nitride layer has a refractive index in the range of about 1.7 to about 2.3.

29. The layered structure of claim 27, wherein at least some of the silicon nano-dots have diameters ranging from about 2 nm to about 10 nm.

30. The layered structure of claim 27, wherein the density of the laser-induced aggregation silicon nano-dots range from about 1×10¹¹/cm² to about 1×10¹²/cm².

31. The layered structure of claim 27, further comprising a second conductive layer.

32. A solar cell comprising a layered structure of claim 27.

33. A photo sensitive element comprising a layered structure of claim 27.

34. A display panel comprising a layered structure of claim 27.

35. A touch panel comprising a display panel of claim 34.

36. A non-volatile memory device comprising a layered structure of claim 27, wherein at least some of the plurality of laser-induced aggregation silicon nano-dots are adapted as storage nodes.
